(19) United States
(12) Patent Application Publication
(10) Pub. No.: US 2022/0371940 A1
(43) Pub. Date: Nov. 24, 2022

(54) ULTRAVIOLET TRANSMISSION GLASS

(71) Applicant: Nippon Electric Glass Co., Ltd., Shiga (JP)

(72) Inventors: Ryota SUZUKI, Shiga (JP); Koichi HASHIMOTO, Shiga (JP)

(21) Appl. No.: 17/761,272

(22) PCT Filed: Sep. 30, 2020
(86) PCT No.: PCT/JP2020/037185

§ 371 Date: Mar. 17, 2022

(30) Foreign Application Priority Data
Oct. 7, 2019 (JP) 2019-184371

(51) Int. Cl. C03C 3/091; C03C 4/00

(52) U.S. Cl. CPC C03C 3/091; C03C 4/0085; C03C 2217/70; C03C 2201/32

(57) ABSTRACT

Devised is a UV transmitting glass having a high transmittance in a deep UV region, and also having high weather resistance. The UV transmitting glass of the present invention is characterized by including as a glass composition, in terms of mass %, 55% to 80% of SiO₂, 1% to 25% of Al₂O₃, 10.8% to 30% of B₂O₃, 0% to 10% of Na₂O, 0% to less than 1.6% of K₂O, 0.1% to 10% of Li₂O+Na₂O+K₂O, 0% to 5% of BaO, and 0% to 1% of Cl, and having an external transmittance at a thickness of 0.5 mm and a wavelength of 200 nm of 38% or more.

### TECHNICAL FIELD

The present invention relates to a UV transmitting glass.

### BACKGROUND ART

Currently, a light source having a high output in a deep UV region (e.g., a wavelength region of from 200 nm to 350 nm) is being developed, and is used for, for example, a UV lamp and a writing device for a magnetic recording medium. In addition, a LW transmitting glass having a high transmittance in the deep LW region (for example, Patent Literatures 1 and 2) is used for the light source.

### CITATION LIST

Patent Literature 1: WO 2016/194780 A1
Patent Literature 2: JP 5847998 B2

### SUMMARY OF INVENTION

### Technical Problem

As the transmittance of the UV transmitting glass in the deep UV region becomes higher, the performance of the above-mentioned light source improves. For example, when such UV transmitting glass is used for the outer casing of a UV lamp for sterilization use, higher sterilization power can be obtained.

However, in the related-art UV transmitting glass, a boron oxide-rich glass composition is often used in order to enhance the transmittance in the deep UV region, and hence its weather resistance is lowered as compared to that of, for example, general borosilicate glass (Pyrex glass) or soda lime glass. Accordingly, there has been a problem in that the product life of an electronic device using such UV transmitting glass is shortened.

The present invention has been made in view of the above-mentioned circumstances, and a technical object of the present invention is to devise a UV transmitting glass having a high transmittance in a deep UV region, and also having high weather resistance.

### Solution to Problem

The inventors of the present invention have made extensive investigations, and as a result, have found that the above-mentioned technical object can be achieved by restricting a glass composition and glass characteristics to predetermined ranges. The finding is proposed as the present invention. That is, according to one embodiment of the present invention, there is provided a UV transmitting glass, comprising as a glass composition, in terms of mass %, 55% to 80% of SiO₂, 1% to 25% of Al₂O₃, 10.8% to 30% of B₂O₃, 0% to 10% of Na₂O, 0% to less than 1.6% of K₂O, 0.1% to 10% of Li₂O+Na₂O+K₂O, 0% to 5% of Ba0, and 0% to 1% of Cl, and having an external transmittance at a thickness of 0.5 mm and a wavelength of 200 nm of 38% or more. Herein, the “external transmittance at a thickness of 0.5 mm and a wavelength of 200 nm” may be measured with a commercially available spectrophotometer (e.g., V-670 manufactured by JASCO Corporation) using a measurement sample having both surfaces thereof polished into optically polished surfaces (mirror surfaces).

In addition, the LW transmitting glass according to the one embodiment of the present invention preferably comprises as the glass composition, in terms of mass %, 65% to 74% of SiO₂, 3.5% to 20% of Al₂O₃, 11.5% to 25% of B₂O₃, 0.1% to 8% of Na₂O, 0% to 1% of K₂O, 1% to 10% of Li₂O+Na₂O+K₂O, 0% to 1.9% of Ba0, 0.01% to 0.5% of Cl, and 0.00001% to 0.00200% of Fe₂O₃+TiO₂.

In addition, in the LW transmitting glass according to the one embodiment of the present invention, when the LW transmitting glass is subjected to a highly accelerated stress test (HAST) at a temperature of 121° C. and a relative humidity of 85% for a test time of 24 hours, a longest side of foreign matter generated on a surface of the glass is preferably 100 pm or less. Herein, the “highly accelerated stress test (HAST) ” may be performed using, for example, a commercially available apparatus (manufactured by, for example, Hirayama Manufacturing Corporation). The “longest side of foreign matter” may be observed using, for example, a digital microscope manufactured by Keyence Corporation.

In addition, the LW transmitting glass according to the one embodiment of the present invention preferably has a temperature corresponding to glass viscosity Logp=6.0 dPa·s of 870° C. or less. Herein, the “temperature corresponding to glass viscosity Logp=6.0 dPa·s” is determined by substituting a strain point, an annealing point, a softening point, a temperature corresponding to glass viscosity Logp=4.0 dPa·s, a temperature corresponding to glass viscosity Logp=3.0 dPa·s, and a temperature corresponding to glass viscosity Logp=2.5 dPa·s, each of which is measured by using a platinum sphere pull up method, and the glass viscosity into the Fulcher equation, and then calculating the temperature corresponding to glass viscosity Logp=6.0 dPa·s.

In addition, the LW transmitting glass according to the one embodiment of the present invention preferably has a temperature corresponding to glass viscosity Logp=4.0 dPa·s of 1,200° C. or less. Herein, the “temperature corresponding to glass viscosity Logp=4.0 dPa·s” may be measured by the platinum sphere pull up method.

In addition, the LW transmitting glass according to the one embodiment of the present invention preferably has an average thermal expansion coefficient in a range of from 30° C. to 380° C. of from 40×10⁻⁷/° C. to 65×10⁻⁷/° C. Herein, the “average thermal expansion coefficient in a range of from 30° C. to 380° C.” may be measured with a commercially available dilatometer.

In addition, the LW transmitting glass according to the one embodiment of the present invention preferably has an external transmittance at a thickness of 0.5 mm and a wavelength of 230 nm of 70% or more. Herein, the “external transmittance at a thickness of 0.5 mm and a wavelength of 230 nm” may be measured with a commercially available spectrophotometer (e.g., V-670 manufactured by JASCO Corporation) using a measurement sample having both surfaces thereof polished into optically polished surfaces (mirror surfaces).

In addition, the LW transmitting glass according to the one embodiment of the present invention preferably satisfies a relationship of T₂₀₀/T₂₆₀≥0.45, where T₂₀₀ represents the external transmittance (%) at a thickness of 0.5 mm and a wavelength of 200 nm, and T₂₅₀ represents an external transmittance (%) at a thickness of 0.5 mm and a wavelength of 260 nm. Herein, the “external transmittance at a thickness of 0.5 mm and a wavelength of 260 nm” may be measured with a commercially available spectrophotometer (e.g., V-670 manufactured by JASCO Corporation) using a measurement sample having both surfaces thereof polished into optically polished surfaces (mirror surfaces).

In addition, the LW transmitting glass according to the one embodiment of the present invention preferably has a functional film formed on a glass surface thereof.

In addition, the LW transmitting glass according to the one embodiment of the present invention preferably has a lens structure formed on a glass surface thereof.

In addition, the LW transmitting glass according to the one embodiment of the present invention preferably has a prism structure formed on a glass surface thereof.

In addition, the UV transmitting glass according to the one embodiment of the present invention preferably has an adhesive layer formed on a glass surface thereof.

In addition, the UV transmitting glass according to the one embodiment of the present invention preferably has a sheet shape or a tube shape, and has a thickness of from 0.1 mm to 3.0 mm.

In addition, the UV transmitting glass according to the one embodiment of the present invention preferably has a tube shape, and has an inner diameter of 1 mm or more.

In addition, the UV transmitting glass according to the one embodiment of the present invention is preferably used for any one of a UV light-emitting diode (LED), a semiconductor package, a light-receiving element-encapsulating package, a UV light-emitting lamp, and a photomultiplier tube.

### BRIEF DESCRIPTION OF DRAWINGS

FIG. 1 is a transmittance curve of Sample No. 13 in the “Examples” section in the wavelength region of from 200 nm to 400 nm and at a thickness of 0.5 mm.

### DESCRIPTION OF EMBODIMENTS

A UV transmitting glass of the present invention comprises as a glass composition, in terms of mass %, 55% to 80% of SiO₂, 1% to 25% of Al₂O₃, 10.8% to 30% of B₂O₃, 0% to 10% of Na₂O, 0% to less than 1.6% of K₂O, 0.1% to 10% of Li₂O+Na₂O+K₂O, 0% to 5% of BaO, and 0% to 1% of Cl. The reasons why the contents of the components are limited as described above are described below. In the description of the content of each component, the expression “%” means “mass %” unless otherwise specified.

SiO₂ is a main component for forming the skeleton of the glass. The content of SiO₂ is preferably from 55% to 80%, from 60% to 78%, from 62% to 75%, or from 65% to 74%, particularly preferably from 66% to 72%. When the content of SiO₂ is too low, a Young's modulus, acid resistance, and weather resistance are liable to be reduced. Meanwhile, when the content of SiO₂ is too high, a viscosity at high temperature is liable to be increased to reduce meltability. Besides, a devitrified crystal, such as cristobalite, is liable to precipitate, and a liquidus temperature is liable to be increased. When the content of SiO₂ falls outside the above-mentioned ranges, the glass is liable to undergo phase separation, and the weather resistance is liable to be reduced.

Al₂O₃ is a component that enhances the weather resistance and the Young's modulus, and is also a component that suppresses phase separation and devitrification. The content of Al₂O₃ is preferably from 1% to 25%, from 2% to 20%, from 3.5% to 10%, or from 4% to 7%, particularly preferably from 4.5% to 6.5%. In addition, another preferred range thereof is from 1% to 25%, from 3% to 19%, from 3.5% to 15%, from 4% to 12%, from 4.3% to 10%, from 5% to 9%, from 6.5% to 8.8%, or from 7% to 8.6%, particularly preferably from 7.5% to 8.5%. When the content of Al₂O₃ falls within those ranges, a transmittance and the weather resistance are improved, and besides, the glass can easily be adjusted to a viscosity that enables low-cost production. When the content of Al₂O₃ is too low, the weather resistance and the Young's modulus are liable to be reduced, and besides, the glass is liable to undergo phase separation or devitrification. Meanwhile, when the content of Al₂O₃ is too high, the viscosity at high temperature is liable to be increased to reduce the meltability.

B₂O₃ is a component that enhances the meltability, devitrification resistance, and a transmittance in a deep UV region, and is also a component that ameliorates vulnerability to flaws to enhance strength. The content of B₂O₃ is preferably from 10.8% to 30%, from 11.5% to 25%, from 13% to 24%, from 14% to 23%, from 15% to 22%, from 15.5% to 21%, from 15.8% to 20%, or from 16% to 19%, particularly preferably from 16.1% to 18.1%. When the content of B₂O₃ is too low, it becomes difficult to provide the above-mentioned effects. Meanwhile, when the content of B₂O₃ is too high, the Young's modulus, the acid resistance, and the weather resistance are liable to be reduced. In addition, the glass is liable to undergo phase separation, and the weather resistance is liable to be reduced.

Al₂O₃ and B₂O₃ are each a component that enhances the devitrification resistance. The total content of Al₂O₃ and B₂O₃ is preferably from 15% to 30%, from 16% to 28%, or from 17% to 27%, particularly preferably from 19% to 26%. In addition, another preferred range thereof is from 15% to 30%, from 18% to 28.5%, or from 22% to 27.5%, particularly preferably from 25% to 26.5%. When the total content of Al₂O₃ and B₂O₃ falls within those ranges, the transmittance and the weather resistance are improved, and besides, the glass can easily be adjusted to a viscosity that enables low-cost production. When the content of Al₂O₃+B₂O₃ is too low, the glass is liable to devitrify. Meanwhile, when the total content of Al₂O₃ and B₂O₃ is too high, the glass composition loses its component balance, with the result that the glass is liable to devitrify contrarily.

The content of B₂O₃—Al₂O₃ is preferably from 10% to 20%, from 11% to 19%, or from 12% to 17%, particularly preferably from 13% to 16%. In addition, another preferred range thereof is from 5% to 15%, from 6% to 13%, or from 7% to 12%, particularly preferably from 8% to 9.9%. When the content of B₂O₃—Al₂O₃ falls within those ranges, the transmittance and the weather resistance are improved, and besides, the glass can easily be adjusted to a viscosity that enables low-cost production. When the content of B₂O₃—Al₂O₃ is too low, the transmittance in the deep LW region is liable to be reduced. Meanwhile, when the content of B₂O₃—Al₂O₃ is too high, the weather resistance is reduced. In addition, the glass is liable to undergo phase separation. “B₂O₃—Al₂O₃” is a value obtained by subtracting the content of Al₂O₃ from the content of B₂O₃.

Li₂O is a component that reduces the viscosity at high temperature to remarkably enhance the meltability, and that also contributes to initial melting of glass raw materials. The content of Li₂O is preferably from 0% to 5%, from 0.1% to 3%, from 0.2% to 2%, from 0.5% to 1.9%, or from 0.6% to 1.6%, particularly preferably from 0.7% to 1.2%. In addition, another preferred range thereof is from 0% to 5%, from 0.3% to 4%, or from 0.8% to 3.5%, particularly preferably from 2% to 3%. When the content of Li₂O falls within those ranges, the transmittance and the weather resistance are improved, and besides, the glass can easily be adjusted to a viscosity that enables low-cost production. When the content of Li₂O is too low, the meltability is liable to be reduced, and besides, there is a risk in that a thermal expansion coefficient may be improperly lowered. Meanwhile, when the content of Li₂O is too high, the glass is liable to undergo phase separation. In addition, the batch cost of the glass is increased. Further, the weather resistance is liable to be reduced.

Na₂O is a component that reduces the viscosity at high temperature to remarkably enhance the meltability, and that also contributes to initial melting of glass raw materials. In addition, Na₂O is a component for adjusting the thermal expansion coefficient. The content of Na₂O is preferably from 0% to 10%, from 0.1% to 8%, from 0.5% to 7%, from 0.7% to 6.5%, from 0.8% to 6.2%, from 0.9% to 6%, from 1% to 5.8%, from 1.5% to 5.5%, from 2% to 5.4%, from 3% to 5.3%, or from 3.8% to 5.1%, particularly preferably from 4% to 5%. In addition, another preferred range thereof is from 0% to 10%, from 0.2% to 8.5%, from 0.6% to 7.5%, or from 1.8% to 3.9%, particularly preferably from 2% to 3%. When the content of Na₂O falls within those ranges, the transmittance and the weather resistance are improved, and besides, the glass can easily be adjusted to a viscosity that enables low-cost production. When the content of Na₂O is too low, the meltability is liable to be reduced, and besides, there is a risk in that the thermal expansion coefficient maybe improperly lowered. Meanwhile, when the content of Na₂O is too high, there is a risk in that the thermal expansion coefficient may be improperly increased. Further, the weather resistance is liable to be reduced.

K₂O is a component that reduces the viscosity at high temperature to remarkably enhance the meltability, and that also contributes to initial melting of glass raw materials. In addition, K₂O is a component for adjusting the thermal expansion coefficient. The content of 1(₂0 is preferably from 0% to less than 1.6%, or from 0.1% to 1.5%, particularly preferably from 0.5% to 1%. In addition, another preferred range thereof is from 0% to less than 1.6%, from 0% to 0.9%, from 0% to 0.7%, or from 0% to 0.4%, particularly preferably from 0% to 0.1%. When the content of 1(₂0 falls within those ranges, the transmittance and the weather resistance are improved, and besides, the glass can easily be adjusted to a viscosity that enables low-cost production. When the content of K₂O is too high, there is a risk in that the batch cost may be improperly increased. Further, the glass is liable to undergo phase separation, and the weather resistance is liable to be reduced.

Li₂O, Na₂O, and K₂O are each an alkali metal oxide component that reduces the viscosity at high temperature to remarkably enhance the meltability, and that also contributes to initial melting of glass raw materials. The content of Li₂O+Na₂O+K₂O (total content of Li₂O, Na₂O, and K₂O) is preferably from 0.1% to 10%, from 0.1% to 9.5%, from 0.1% to 9.2%, from 0.1% to 9.0%, from 0.2% to 8.8%, from 0.5% to 8.5%, from 0.8% to 8.2%, from 1.0% to 8.0%, from 2% to 7.8%, from 3% to 7.6%, or from 3.5% to 7.2%, particularly preferably from 4% to 7%. When the content of Li₂O+Na₂O+K₂O is too low, the meltability is liable to be reduced. Meanwhile, when the content of Li₂O+Na₂O+K₂O is too high, the weather resistance is liable to be reduced, and besides, there is a risk in that the thermal expansion coefficient may be improperly increased.

When a mass ratio Li₂O/(Li₂O+Na₂O+K₂O) is too small, the meltability is liable to be reduced, and besides, there is a risk in that the thermal expansion coefficient may be improperly lowered. Meanwhile, when the mass ratio Li₂O/(Li₂O+Na₂O+K₂O) is too large, the glass is liable to undergo phase separation. In addition, the batch cost of the glass is increased. Accordingly, the mass ratio Li₂O/(Li₂O+Na₂O+K₂O) is preferably from 0 to 0.50, from 0.01 to 0.40, from 0.02 to 0.30, or from 0.03 to 0.20, particularly preferably from 0.04 to 0.19. “Li₂O/(Li₂O+Na₂O+K₂O) ” refers to a value obtained by dividing the content of Li₂O by the total content of Li₂O, Na₂O, and K₂O.

When a mass ratio Na₂O/(Li₂O+Na₂O+K₂O) is too small, the meltability is liable to be reduced. Meanwhile, when the mass ratio Na₂O/(Li₂O+Na₂O+K₂O) is too large, an electrical resistivity at the time of melting of the glass is increased, and hence there is a risk in that the glass may be electrolyzed to generate air bubbles in the glass. Accordingly, the mass ratio Na₂O/(Li₂O+Na₂O+K₂O) is preferably from 0.10 to 1.00, from 0.13 to 0.90, from 0.15 to 0.85, from 0.20 to 0.80, or from 0.25 to 0.78, particularly preferably from 0.33 to 0.70. “Na₂O/(Li₂O+Na₂O+K₂O) ” refers to a value obtained by dividing the content of Na₂O by the total content of Li₂O, Na₂O, and K₂O.

When a mass ratio K₂O/(Li₂O+Na₂O+K₂O) is too large, the batch cost of the glass is increased. Accordingly, the mass ratio K₂O/(Li₂O+Na₂O+K₂O) is preferably from 0 to 0.80, from 0 to 0.75, from 0 to 0.70, from 0.01 to 0.60, or from 0.03 to 0.50, particularly preferably from 0.04 to 0.40. In addition, another preferred range thereof is from 0 to 0.80, from 0 to 0.65, from 0 to 0.55, from 0 to 0.45, or from 0 to 0.25, particularly preferably from 0 to 0.10. When the mass ratio K₂O/(Li₂O+Na₂O+K₂O) falls within those ranges, the transmittance and the weather resistance are improved, and besides, the glass can easily be adjusted to a viscosity that enables low-cost production. “K₂O/(Li₂O+Na₂O+K₂O) ” refers to a value obtained by dividing the content of K₂O by the total content of Li₂O, Na₂O, and K₂O.

BaO is a component that enhances the devitrification resistance. When the content of BaO is too high, the glass is liable to undergo phase separation. The content of BaO is preferably from 0% to 5%, from 0.1% to 3%, from 0.5% to 2%, or from 1% to 1.9%. In addition, another preferred range thereof is from 0% to 5%, from 0% to 4%, from 0% to 2.5%, from 0% to 1.5%, or from 0% to 0.4%, particularly preferably from 0% to 0.1%. When the content of Ba0 falls within those ranges, the transmittance is improved, and besides, the glass can easily be adjusted to a viscosity that enables low-cost production.

Cl is a component that acts as a fining agent. The content of Cl is preferably from 0% to 1%, from 0.01% to 0.9%, from 0.02% to 0.5%, from 0.03% to 0.2%, from 0.04% to 0.15%, from 0.05% to 0.10%, from 0.06% to 0.09%, or from 0.07% to 0.08%. When the content of Cl is too low, it becomes difficult to exhibit a fining effect. Meanwhile, when the content of Cl is too high, there is a risk in that a fining gas may remain in the glass as bubbles.

In addition to the above-mentioned components, any other components may be introduced as long as the transmittance in the deep UV region is not significantly reduced. The content of components other than the above-mentioned components is preferably 10% or less, or 7% or less, particularly preferably 5% or less in terms of total content, from the viewpoint of appropriately providing the effects of the present invention.

P₂O₅ is a component that enhances a glass formation ability. When the content of P₂O₅ is too low, the glass becomes unstable, and there is even a risk in that the devitrification resistance may be reduced. Meanwhile, when the content of P₂O₅ is too high, the glass is liable to undergo phase separation, and the weather resistance and water resistance are liable to be reduced. Accordingly, the content of P₂O₅ is preferably from 0% to 5%, from 0.1% to 4%, from 0.3% to 3%, or from 0.5% to 2%, particularly preferably from 1% to 1.5%.

MgO is a component that reduces the viscosity at high temperature to enhance the meltability, and is a component that remarkably enhances the Young's modulus among alkaline earth metal oxides. However, when the content of MgO is too high, the glass is liable to undergo phase separation or devitrification. Accordingly, the content of MgO is preferably from 0% to 3%, from 0% to 2%, or from 0% to 1%, particularly preferably from 0.1% to 0.9%. In addition, another preferred range thereof is from 0% to 3%, from 0% to 2.5%, from 0% to 1.5%, or from 0% to 0.4%, particularly preferably from 0% to 0.1%. When the content of MgO falls within those ranges, the transmittance is improved, and besides, the glass can easily be adjusted to a viscosity that enables low-cost production.

CaO is a component that reduces the viscosity at high temperature to enhance the meltability. In addition, a raw material for introducing CaO is relatively inexpensive among those for alkaline earth metal oxides, and hence CaO is a component that achieves a reduction in raw material cost. However, when the content of CaO is too high, the glass is liable to undergo phase separation, and the weather resistance is liable to be reduced. Accordingly, the content of CaO is preferably from 0% to 3%, from 0% to 1%, from 0.01% to 0.8%, or from 0.1% to 0.5%. In addition, another preferred range thereof is from 0% to 3%, from 0% to 2.5%, from 0% to 1.5%, or from 0% to 0.4%, particularly preferably from 0% to 0.1%. When the content of CaO falls within those ranges, the transmittance is improved, and besides, the glass can easily be adjusted to a viscosity that enables low-cost production.

SrO is a component that enhances the devitrification resistance. However, when the content of SrO is too high, the glass is liable to undergo phase separation. The content of SrO is preferably from 0% to 3%, from 0% to 2%, or from 0% to 1%, particularly preferably from 0.1% to 0.5%. In addition, another preferred range thereof is from 0% to 3%, from 0% to 2.5%, from 0% to 1.5%, or from 0% to 0.4%, particularly preferably from 0% to 0.1%. When the content of SrO falls within those ranges, the transmittance is improved, and besides, the glass can easily be adjusted to a viscosity that enables low-cost production.

MgO, CaO, SrO, and BaO are each a component that reduces the viscosity at high temperature to enhance the meltability. However, when the content of MgO+CaO+SrO+BaO is too high, the glass is liable to devitrify. In addition, the glass is liable to undergo phase separation. Accordingly, the content of MgO+CaO+SrO+BaO (total content of MgO, CaO, SrO, and BaO) is preferably from 0% to 5%, or from 0.1% to 3%, particularly preferably from 0.5% to 2%. In addition, another preferred range thereof is from 0% to 5%, from 0% to 4%, from 0% to 3%, from 0% to 2.5%, from 0% to 1.5%, or from 0% to 0.4%, particularly preferably from 0% to 0.1%. When the content of MgO+CaO+SrO+BaO falls within those ranges, the transmittance is improved, and besides, the glass can easily be adjusted to a viscosity that enables low-cost production.

When a mass ratio (MgO+CaO+SrO+BaO )/Al₂O₃ is too small, the devitrification resistance is reduced to make forming into a sheet shape or a tube shape difficult. Meanwhile, when the mass ratio (MgO+CaO+SrO+BaO)/Al₂O₃ is too large, the glass is liable to undergo phase separation. In addition, there is a risk in that a density and the thermal expansion coefficient may be improperly increased. Accordingly, the mass ratio (MgO+CaO+SrO+BaO )/Al₂O₃ is preferably from 0 to 1, from 0.1 to 0.95, from 0.2 to 0.90, from 0.3 to 0.80, or from 0.4 to 0.70, particularly preferably from 0.41 to 0.66. In addition, another preferred range thereof is from 0 to 1, from 0 to 0.5, from 0 to 0.4, from 0 to 0.3, or from 0 to 0.2, particularly preferably from 0 to 0.1. When the mass ratio (MgO+CaO+SrO+BaO)/Al₂O₃ falls within those ranges, the transmittance is improved, and besides, the glass can easily be adjusted to a viscosity that enables low-cost production. “(MgO+CaO+SrO+BaO)/Al₂O₃” refers to a value obtained by dividing the total content of MgO, CaO, SrO, and BaO by the content of Al₂O₃.

When the content of B₂O₃—(MgO+CaO+SrO+BaO) is too low, the transmittance in the deep UV region is liable to be lowered, and besides, the density is liable to be increased. Meanwhile, when the content of B₂O₃—(MgO+CaO+SrO+BaO) is too high, the weather resistance is liable to be reduced. Accordingly, the content of B₂O₃—(MgO+CaO+SrO+BaO) is preferably from 10% to 20%, from 11% to 19%, from 12% to 18%, or from 13% to 17%, particularly preferably from 14% to 16%. In addition, another preferred range thereof is from 10% to 20%, from 12% to 19.9%, from 14% to 19.7%, or from 16% to 19.4%, particularly preferably from 17% to 19%. When the content of B₂O₃—(MgO+CaO+SrO+BaO) falls within those ranges, the transmittance is improved, and besides, the glass can easily be adjusted to a viscosity that enables low-cost production. “B₂O₃—(MgO+CaO+SrO+BaO)” refers to a value obtained by subtracting the total content of MgO, CaO, SrO, and BaO from the content of B₂O₃.

When a mass ratio (MgO+CaO+SrO+BaO)/(SiO₂+Al₂O₃+B₂O₃) is too small, the viscosity at high temperature is increased to increase a melting temperature, and hence the manufacturing cost of a glass sheet or a glass tube is liable to rise. Meanwhile, when the mass ratio (MgO+CaO+SrO+BaO)/(SiO₂+Al₂O₃+B₂O₃) is too large, the transmittance in the deep UV region is liable to be reduced. Accordingly, the mass ratio (MgO+CaO+SrO+BaO)/(SiO₂+Al₂O₃+B₂O₃) is preferably from 0 to 0.1, from 0.001 to 0.09, from 0.002 to 0.08, from 0.003 to 0.08, from 0.004 to 0.0.07, from 0.005 to 0.06, from 0.007 to 0.05, from 0.008 to 0.04, or from 0.009 to 0.03, particularly preferably from 0.01 to 0.02. In addition, another preferred range thereof is from 0 to 0.1, from 0 to 0.09, from 0 to 0.08, from 0 to 0.0.07, from 0 to 0.06, from 0 to 0.05, from 0 to 0.04, or from 0 to 0.03, particularly preferably from 0 to 0.01. When the mass ratio (MgO+CaO+SrO+BaO)/(SiO₂+Al₂O₃+B₂O₃) falls within those ranges, the transmittance is improved, and besides, the glass can easily be adjusted to a viscosity that enables low-cost production. The “(mass ratio (MgO+CaO+SrO+BaO)/(SiO₂+Al₂O₃+B₂O₃)” refers to a value obtained by dividing the total content of MgO, CaO, SrO, and BaO by the total content of SiO₂, Al₂O₃, and B₂O₃.

ZrO₂ is a component that enhances the weather resistance and the acid resistance, but when a large amount thereof is contained in the glass composition, the glass is liable to devitrify. Accordingly, the content of ZrO₂ is preferably from 0% to 0.1%, or from 0.001% to 0.02%, particularly preferably from 0.0001% to 0.01%.

ZnO is a component that reduces the viscosity at high temperature without reducing a viscosity at low temperature. In addition, ZnO is also a component that enhances the weather resistance. Meanwhile, when the content of ZnO is too high, the following tendency is observed: the glass undergoes phase separation, the devitrification resistance is reduced, or the density is increased. The content of ZnO is preferably from 0% to 5%, from 0.1% to 4%, from 0.3% to 3%, from 0.5% to 2.9%, or from 0.7% to 2.8%, particularly preferably from 1.3% to 2.4%. In addition, another preferred range thereof is from 0% to 5%, from 0% to 4.5%, from 0% to 3.5%, from 0% to 2.5%, from 0% to 1.5%, or 0% to 0.3%, particularly preferably from 0% to 0.1%. When the content of ZnO falls within those ranges, the transmittance is improved, and besides, the glass can easily be adjusted to a viscosity that enables low-cost production.

Fe₂O₃ is a component that reduces the transmittance in the deep UV region. The content of Fe₂O₃ is preferably 0.0010% (10 ppm) or less, from 0.00001% to 0.0008% (from 0.1 ppm to 8 ppm), or from 0.00001% to 0.0006% (from 0.1 ppm to 6 ppm). “Fe₂O₃” includes both of ferric oxide and ferrous oxide, and ferrous oxide is treated in terms of ferric oxide. Other multivalent oxides are also similarly treated with reference to indicated oxides.

An Fe ion in iron oxide exists in the state of being Fe²⁺ or Fe³⁺. When the ratio of Fe²⁺ is too low, a transmittance for a deep UV ray is liable to be reduced. Accordingly, a mass ratio Fe²⁺ (Fe²⁺+Fe³⁺) in the iron oxide contained in the UV transmitting glass of the present invention is preferably 0.1 or more, 0.2 or more, 0.3 or more, or 0.4 or more, particularly preferably 0.5 or more.

TiO₂ is a component that reduces the transmittance in the deep UV region. The content of TiO₂ is preferably 0.0010% (10 ppm) or less, 0.00030% (3 ppm) or less, or from 0.00001% to 0.00015% (from 0.1 ppm to 1.5 ppm). When the content of TiO₂ is too high, the glass is liable to be colored to reduce the transmittance in the deep UV region.

The total content of Fe₂O₃ and TiO₂ is preferably 0.0020% (20 ppm) or less, or 0.0010% (10 ppm) or less, particularly preferably from 0.00001% to 0.0007% (from 0.1 ppm to 7 ppm). When the total content of Fe₂O₃ and TiO₂ is too high, the glass is liable to be colored to reduce the transmittance in the deep UV region.

F is a component that acts as a fining agent, and is a component that reduces the viscosity to enhance the meltability. The content of F is preferably from 0% to 3%, from 0% to 2%, from 0.1% to 1.5%, or from 0.5% to 1.5%.

Sb₂O₃ is a component that acts as a fining agent. The content of Sb₂O₃ is preferably 0.1% or less, 0.08% or less, 0.06% or less, 0.04% or less, 0.02% or less, or 0.01% or less, particularly preferably less than 0.005%. When the content of Sb₂O₃ is too high, the transmittance in the deep UV region is liable to be reduced.

SnO₂ is a component that acts as a fining agent. The content of SnO₂ is preferably 0.2% or less, 0.17% or less, 0.14% or less, 0.11% or less, 0.08% or less, 0.05% or less, 0.02% or less, 0.01% or less, or 0.005% or less, particularly preferably less than 0.005%. When the content of SnO₂ is too high, the transmittance in the deep UV region is liable to be reduced.

F, Cl, and SnO₂ are each a component that acts as a fining agent. The content of F+Cl+SnO₂ (total content of F, Cl, and SnO₂) is preferably from 10 ppm to 30,000 ppm (from 0.001% to 3%), from 50 ppm to 20,000 ppm, from 100 ppm to 10,000 ppm, from 250 ppm to 5,000 ppm, or from 500 ppm to 3,000 ppm, particularly preferably from 700 ppm to 2,000 ppm. When the content of F+Cl+SnO₂ is too low, it becomes difficult to exhibit a fining effect. Meanwhile, when the content of F+Cl+SnO₂ is too high, there is a risk in that a fining gas may remain in the glass as bubbles.

The UV transmitting glass of the present invention preferably has the following glass characteristics.

After the UV transmitting glass of the present invention is subjected to a highly accelerated stress test (HAST) at a temperature of 121° C. and a relative humidity of 85% for a test time of 24 hours, the longest side of foreign matter generated on the surface of the glass is preferably 100 pm or less, 80 pm or less, 60 pm or less, or 40 pm or less, particularly preferably 20 pm or less. When large foreign matter is generated on the glass surface after the highly accelerated stress test, the transmittance in the deep UV region is reduced to shorten the product life of an electronic device.

A temperature corresponding to glass viscosity Logρ=6.0 dPa·s is preferably 870° C. or less, 860° C. or less, 855° C. or less, 850° C. or less, or 840° C. or less, particularly preferably 835° C. or less. The temperature corresponding to glass viscosity Logρ=6.0 dPa·s is a temperature suitable for softening the UV transmitting glass to perform encapsulation with another material (e.g., a diode to be encapsulated inside a tube glass). When this temperature is too high, an electronic part to be encapsulated inside is deteriorated, and hence it becomes difficult to exhibit its function.

A temperature corresponding to glass viscosity Logp=4.0 dPa·s is preferably 1,200° C. or less, 1,180° C. or less, 1,150° C. or less, 1,120° C. or less, 1,100° C. or less, 1,080° C. or less, or 1,060° C. or less, particularly preferably 1,040° C. or less. The temperature corresponding to glass viscosity Logp=4.0 dPa·s is a temperature suitable for sealing one end of a glass tube. When this temperature is too high, energy for heating the glass tube is increased, leading to an increase in manufacturing cost.

An average thermal expansion coefficient in a range of from 30° C. to 380° C. is preferably from 40×10⁻⁷/° C. to 65×10⁻⁷/° C., from 41×10⁻⁷/° C. to 64×10⁻⁷/° C., from 42×10⁻⁷/° C. to 62'10⁻⁷/° C., from 43×10⁻⁷/° C. to 60×10⁻⁷/° C., from 44×10⁻⁷/° C. to 58×10⁻⁷/° C., or from 45×10⁻⁷/° C. to 55×10⁻⁷/° C., particularly preferably from 46×10⁻⁷/° C. to 52×10⁻⁷/° C. When the average thermal expansion coefficient in a range of from 30° C. to 380° C. is too low, there is a risk in that, at the time of encapsulation with another material (e.g., a diode to be encapsulated inside a tube glass) , a strain due to a difference in thermal expansion coefficient may occur at an interface between the glass and the other material to break the glass. Meanwhile, when the average thermal expansion coefficient in a range of from 30° C. to 380° C. is too high, there is a risk in that the glass may be broken owing to thermal shock or the like when the glass is subjected to thermal processing.

An external transmittance at a thickness of 0.5 mm and a wavelength of 200 nm is preferably 38% or more, 40% or more, 45% or more, 50% or more, 55% or more, 57% or more, or 59% or more, particularly preferably 60% or more. When the external transmittance at a thickness of 0.5 mm and a wavelength of 200 nm is too low, it becomes difficult to transmit deep UV light, and hence the performance of a light source or electronic device to be mounted is liable to be reduced.

An external transmittance at a thickness of 0.5 mm and a wavelength of 230 nm is preferably 70% or more, 73% or more, or 74% or more, particularly preferably 75% or more. When the external transmittance at a thickness of 0.5 mm and a wavelength of 230 nm is too low, it becomes difficult to transmit deep UV light, and hence the performance of a light source or electronic device to be mounted is liable to be reduced.

An external transmittance at a thickness of 0.5 mm and a wavelength of 260 nm is preferably 80% or more, or 82% or more, particularly preferably 83% or more. When the external transmittance at a thickness of 0.5 mm and a wavelength of 260 nm is too low, it becomes difficult to transmit deep UV light, and hence the performance of a light source or electronic device to be mounted is liable to be reduced.

When the external transmittance (%) at a thickness of 0.5 mm and a wavelength of 200 nm is represented by T₂₀₀, and the external transmittance (%) at a thickness of 0.5 mm and a wavelength of 260 nm is represented by T₂₆₀, a relationship of T₂₀₀/T₂₆₀≥0.45 is preferably satisfied, a relationship of T₂₀₀/T₂₆₀≥0.50 is more preferably satisfied, a relationship of T₂₀₀/T₂₆₀≥0.55 is still more preferably satisfied, a relationship of T₂₀₀/T₂₆₀≥0.60 is still more preferably satisfied, and a relationship of T₂₀₀/T₂₆₀0.65 is particularly preferably satisfied. When the value of T₂₀₀/T₂₆₀ is too small, it becomes difficult to transmit deep UV light, and hence the performance of a light source or electronic device to be mounted is liable to be reduced.

A strain point is preferably 400° C. or more, or 410° C. or more, particularly preferably 415° C. or more. When the strain point is too low, unintended deformation of the glass is liable to occur when a functional film is formed on the glass surface at high temperature.

A softening point is preferably 850° C. or less, 800° C. or less, or 750° C. or less, particularly preferably 700° C. or less. When the softening point is too high, a load on a glass melting kiln is increased, and hence the manufacturing cost of the glass is liable to rise.

A temperature at glass viscosity Logp=2.5 dPa·s is preferably 1,630° C. or less, 1,600° C. or less, 1,560° C. or less, 1,540° C. or less, 1,520° C. or less, or 1,500° C. or less, particularly preferably 1,480° C. or less. When the temperature at glass viscosity Logρ=2.5 dPa·s is too high, the meltability is reduced, and hence the manufacturing cost of the glass is liable to rise.

A liquidus temperature is preferably 1,050° C. or less, 1,000° C. or less, 950° C. or less, or 900° C. or less, particularly preferably 850° C. or less. A glass viscosity at the liquidus temperature is preferably 4.0 dPa·s or more, 4.3 dPa·s or more, 4.5 dPa·s or more, 4.8 dPa·s or more, 5.1 dPa·s or more, or 5.3 dPa·s or more, particularly preferably 5.5 dPa·s or more in terms of Logρ. When the liquidus temperature is too high, the devitrification resistance is reduced to make forming into a desired shape difficult. In addition, when the glass viscosity at the liquidus temperature is too low, the devitrification resistance is reduced to make forming into a desired shape difficult.

The UV transmitting glass of the present invention preferably has a functional film formed on the glass surface thereof, and for example, an antireflection film, a reflective film, a high-pass filter, a low-pass filter, or a band-pass filter is preferably formed thereon. In addition, for the purpose of further enhancing the weather resistance, it is also preferred that a silica film or the like be formed on the glass surface.

It is also preferred that the UV transmitting glass of the present invention have a lens structure formed on the glass surface thereof. When the lens structure, such as a concave lens, a convex lens, a Fresnel lens, or a lens array, is formed on the glass surface, deep UV light can be condensed or scattered.

It is also preferred that the UV transmitting glass of the present invention have a prism structure formed on the glass surface thereof. When the prism structure is formed on the glass surface, deep UV light can be refracted.

The UV transmitting glass of the present invention may be used for a semiconductor package. In this case, the UV transmitting glass preferably has an adhesive layer formed on the glass surface thereof. An organic substance, an inorganic substance, a mixture thereof, or the like maybe used as the adhesive layer. For example, a UV-curable adhesive or gold-tin-based solder maybe used. In order to enhance the strength of the adhesive layer, an inorganic filler may be added into the UV-curable adhesive.

The shape of the UV transmitting glass of the present invention is not particularly limited, and may be, for example, a flat sheet shape, a curved sheet shape, a straight tube shape, a curved tube shape, a rod shape, a spherical shape, a container shape, or a block shape.

When the shape is a flat sheet shape, the dimensions of a main surface thereof are preferably 100 mm×100 mm or more, 200 mm×200 mm or more, 400 mm×400 mm or more, or 1,000 mm×1,000 mm or more, particularly preferably 2,000 mm×2,000 mm or more. As the dimensions of the main surface become larger, the number of small-piece glass sheets to be obtained increases, and hence a reduction in manufacturing cost of an electronic device can be achieved more easily.

When the shape is a tube shape, the inner diameter thereof is preferably 1 mm or more, 1.3 mm or more, 1.5 mm or more, 2 mm or more, 2.5 mm or more, 3 mm or more, 3.5 mm or more, 5 mm or more, 10 mm or more, 20 mm or more, or 25 mm or more, particularly preferably from 30 mm to 200 mm. As the inner diameter becomes larger, it becomes easier to encapsulate an electronic part inside the glass tube, and for example, it becomes easier to encapsulate a filament or a switch.

The UV transmitting glass of the present invention has a thickness of preferably from 0.1 mm to 3.0 mm, from 0.2 mm to 1.0 mm, or from 0.3 mm to 0.6 mm. When the thickness is increased, the transmittance in the deep UV region is reduced. However, by virtue of having a high transmittance in the deep UV region, the UV transmitting glass of the present invention can secure a high transmittance even when having a larger thickness than a related-art product.

The surface roughness Ra of the glass surface is preferably 10 nm or less, 9 nm or less, 8 nm or less, 7 nm or less, 6 nm or less, 5 nm or less, 4 nm or less, 3 nm or less, or 2 nm or less, particularly preferably 1 nm or less. When the surface roughness Ra of the glass surface is too large, the transmittance for a deep UV ray tends to be reduced.

The UV transmitting glass of the present invention is preferably used for any one of a UV light-emitting diode (LED), a semiconductor package, a light-receiving element-encapsulating package, a UV light-emitting lamp, and a photomultiplier tube. As the semiconductor light-receiving element-encapsulating package, the UV transmitting glass is preferably used for a UV light sensor, a flame sensor, or the like. Meanwhile, without being limited to UV light, the UV transmitting glass may also be used for a package encapsulating, for example, a CCD sensor or CMOS sensor that receives visible light, or a Laser Imaging Detection and Ranging (LiDER) sensor that receives infrared light. As the UV light-emitting lamp, the UV transmitting glass is preferably used for a high-pressure UV lamp, a low-pressure UV lamp, an excimer lamp, or the like. Meanwhile, without being limited to the UV light-emitting lamp, the UV transmitting glass may also be used for a lamp that emits visible light or infrared light.

The UV transmitting glass of the present invention may be produced by, for example, blending various glass raw materials to obtain a glass batch, melting the glass batch, and fining and homogenizing the resultant molten glass, followed by forming into a predetermined shape.

Synthetic silica is preferably used as part of the glass raw materials, and it is particularly preferred to use particulate synthetic silica produced by a gas-phase reaction method or a liquid-phase reaction method. The average particle diameter of the synthetic silica is preferably 100 μm or less, more preferably from 5 μm to 90 μm. The synthetic silica is, for example, amorphous silica, spherical silica, or a mixture thereof. In addition, the ratio of the synthetic silica in all silica sources in the glass raw materials is preferably from 90 mass % to 100 mass %. When such raw materials are used, the transmittance in the deep UV region can be enhanced.

A reducing agent is preferably used as part of the glass raw materials. With this configuration, Fe³⁺ contained in the glass is reduced to improve the transmittance for a deep UV ray. A material such as wood powder, carbon powder, metal aluminum, metal silicon, or aluminum fluoride may be used as the reducing agent. Of those, metal silicon or aluminum fluoride is preferred.

The addition amount of metal silicon is preferably from 0.001 mass % to 3 mass %, from 0.005 mass % to 2 mass %, from 0.01 mass % to 1 mass %, from 0.1 mass % to 0.8 mass %, or from 0.15 mass % to 0.5 mass %, particularly preferably 0.2 mass % to 0.3 mass % with respect to the total mass of the glass batch. When the addition amount of metal silicon is too small, Fe³⁺ contained in the glass is not reduced, and hence the transmittance for a deep UV ray is liable to be reduced. Meanwhile, when the addition amount of metal silicon is too large, the glass tends to be colored brown.

The addition amount of aluminum fluoride (AlF₃) is preferably from 0.01 mass % to 2 mass %, from 0.05 mass % to 1.5 mass %, or from 0.3 mass % to 1.5 mass % in terms of F with respect to the total mass of the glass batch. Meanwhile, when the addition amount of aluminum fluoride is too large, there is a risk in that a F gas may remain in the glass as bubbles.

### EXAMPLES

The present invention is hereinafter described by way of Examples. The following Examples are merely examples. The present invention is by no means limited to the following Examples.

Examples of the present invention (Sample Nos. 1 to 48) and Comparative Examples (Sample Nos. 49 to 52) are shown in Tables 1 to 6.

TABLE 1

| | | No. 1 | No. 2 | No. 3 | No. 4 | No. 5 |
|---|---|---|---|---|---|---|
| Composition | SiO₂ | 66.99 | 71.46 | 71.46 | 70.46 | 70.46 |
| (mass %) | Al₂O₃ | 5.21 | 5.21 | 5.21 | 4.71 | 4.71 |
| | B₂O₃ | 19.0 | 17.0 | 17.4 | 18.9 | 19.1 |
| | Li₂O | 0.80 | 0.80 | 0.80 | 0.80 | 0.80 |
| | Na₂O | 2.32 | 2.32 | 2.32 | 2.32 | 2.32 |
| | K₂O | 1.57 | 1.57 | 1.57 | 1.57 | 1.57 |
| | MgO | 0.00 | 0.00 | 0.00 | 0.00 | 0.00 |
| | CaO | 0.00 | 0.00 | 0.00 | 0.00 | 0.00 |
| | SrO | 1.68 | 0.00 | 0.00 | 0.00 | 0.00 |
| | BaO | 0.00 | 0.00 | 0.00 | 0.00 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00000 | 0.00000 | 0.00000 | 0.00000 | 0.00010 |
| | F | 2.35 | 1.55 | 1.15 | 1.15 | 0.95 |
| | Cl | 0.085 | 0.085 | 0.090 | 0.090 | 0.090 |
| | SnO₂ | 0.00 | 0.00 | 0.00 | 0.00 | 0.00 |
| | Fe₂O₃ | 0.0005 | 0.0010 | 0.0010 | 0.0010 | 0.0000 |
| MgO + CaO + SrO + BaO | | 1.68 | 0.00 | 0.00 | 0.00 | 0.00 |
| (MgO + CaO + SrO + Ba)/Al₂O₃ | | 0.32 | 0.00 | 0.00 | 0.00 | 0.00 |
| B₂O₃ − (MgO + CaO + SrO + BaO) | | 17.3 | 17.0 | 17.4 | 18.9 | 19.1 |
| (MgO + CaO + SrO + BaO)/(SiO₂ + | | 0.018 | 0.000 | 0.000 | 0.000 | 0.000 |
| Al₂ O₃ + B₂O₃) | | | | | | |
| B₂O₃ − Al₂O₃ | | 13.8 | 11.8 | 12.2 | 14.2 | 14.4 |
| Li₂O + Na₂O + K₂O | | 4.690 | 4.690 | 4.690 | 4.690 | 4.690 |
| Li₂O/(Li₂O + Na₂O + K₂O) | | 0.171 | 0.171 | 0.171 | 0.171 | 0.171 |
| Na₂O/(Li₂O + Na₂O + K₂O) | | 0.495 | 0.495 | 0.495 | 0.495 | 0.495 |
| K₂O/(Li₂O + Na₂O + K₂O) | | 0.335 | 0.335 | 0.335 | 0.335 | 0.335 |
| TiO₂ + Fe₂O₃ | | 0.00050 | 0.00100 | 0.00100 | 0.00100 | 0.00010 |
| F + Cl + SnO₂ | | 2.435 | 1.635 | 1.240 | 1.240 | 1.040 |
| ρ [g/cm³] | | 2.23 | 2.20 | 2.20 | 2.19 | 2.19 |
| α [×10⁻⁷/° C.] | | 44.2 | 41.8 | 41.2 | 41.5 | 41.0 |
| Ps [° C.] | | 422 | 413 | 415 | 415 | 415 |
| Ta [° C.] | | 469 | 462 | 464 | 462 | 463 |
| Ts [° C.] | | 693 | 703 | 703 | 695 | 695 |
| 10^{6.0} dPa · s [° C.] | | 820 | 857 | 848 | 831 | 835 |
| 10^{4.0} dPa · s [° C.] | | 1,092 | 1,182 | 1,157 | 1,121 | 1,135 |
| 10^{3.0} dPa · s [° C.] | | 1,336 | 1,435 | 1,413 | 1,371 | 1,391 |
| 10^{2.5} dPa · s [° C.] | | 1,518 | 1,622 | 1,604 | 1,557 | 1,583 |
| TL [° C.] | | 866 | 902 | 888 | 845 | 843 |
| logηTL [dPa · s] | | 5.6 | 5.6 | 5.7 | 5.9 | 5.9 |
| Transmittance λ = 260 nm t = 0.5 mm | | Unmeasured | Unmeasured | Unmeasured | Unmeasured | Unmeasured |
| Transmittance λ = 230 nm t = 0.5 mm | | Unmeasured | Unmeasured | Unmeasured | Unmeasured | Unmeasured |
| Transmittance λ = 200 nm t = 0.5 mm | | Unmeasured | Unmeasured | Unmeasured | Unmeasured | Unmeasured |
| T200/T260 | | Unmeasured | Unmeasured | Unmeasured | Unmeasured | Unmeasured |
| Weather resistance | | ∘ | ∘ | ∘ | ∘ | ∘ |
| | | No. 6 | No. 7 | No. 8 | No. 9 | No. 10 |
| Composition | SiO₂ | 70.46 | 70.46 | 69.46 | 66.99 | 69.46 |
| (mass %) | Al₂O₃ | 4.71 | 4.71 | 5.71 | 5.21 | 5.71 |
| | B₂O₃ | 19.1 | 19.1 | 19.1 | 19.6 | 19.1 |
| | Li₂O | 0.80 | 0.50 | 0.50 | 0.80 | 0.75 |
| | Na₂O | 3.32 | 3.32 | 3.32 | 3.32 | 3.32 |
| | K₂O | 0.57 | 0.87 | 0.87 | 1.57 | 1.56 |
| | MgO | 0.00 | 0.00 | 0.00 | 0.00 | 0.00 |
| | CaO | 0.00 | 0.00 | 0.00 | 0.55 | 0.00 |
| | SrO | 0.00 | 0.00 | 0.00 | 0.00 | 0.00 |
| | BaO | 0.00 | 0.00 | 0.00 | 1.13 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00000 | 0.00000 | 0.00100 | 0.00000 | 0.00000 |
| | F | 0.95 | 0.95 | 0.95 | 0.75 | 0.00 |
| | Cl | 0.090 | 0.090 | 0.090 | 0.100 | 0.100 |
| | SnO₂ | 0.00 | 0.00 | 0.00 | 0.00 | 0.00 |
| | Fe₂O₃ | 0.0010 | 0.0010 | 0.0010 | 0.0010 | 0.0010 |

| | | | | | |
|---|---|---|---|---|---|
| MgO + CaO + SrO + BaO | 0.00 | 0.00 | 0.00 | 1.68 | 0.00 |
| (MgO + CaO + SrO + Ba)/Al₂O₃ | 0.00 | 0.00 | 0.00 | 0.32 | 0.00 |
| B₂O₃ − (MgO + CaO + SrO + BaO) | 19.1 | 19.1 | 19.1 | 17.9 | 19.1 |
| (MgO + CaO + SrO + BaO)/(SiO₂ + | 0.000 | 0.000 | 0.000 | 0.018 | 0.000 |
| Al₂ O₃ + B₂O₃) | | | | | |
| B₂O₃ − Al₂O₃ | 14.4 | 14.4 | 13.4 | 14.4 | 13.4 |
| L i₂O + Na₂O + K₂O | 4.690 | 4.690 | 4.690 | 5.690 | 5.630 |
| Li₂O/(Li₂O + Na₂O + K₂O) | 0.171 | 0.107 | 0.107 | 0.141 | 0.133 |
| Na₂O/(Li₂O + Na₂O + K₂O) | 0.708 | 0.708 | 0.708 | 0.583 | 0.590 |
| K₂O/(Li₂O + Na₂O + K₂O) | 0.122 | 0.186 | 0.186 | 0.276 | 0.277 |
| TiO₂ + Fe₂O₃ | 0.00100 | 0.00100 | 0.00200 | 0.00100 | 0.00100 |
| F + Cl + SnO₂ | 1.040 | 1.040 | 1.040 | 0.850 | 0.100 |
| ρ [g/cm³] | 2.20 | 2.19 | 2.19 | 2.24 | 2.21 |
| α [×10⁻⁷/° C.] | 41.5 | 41.8 | 43.1 | 44.8 | 43.6 |
| Ps [° C.] | 422 | 416 | 409 | 428 | 444 |
| Ta [° C.] | 467 | 464 | 459 | 473 | 490 |
| Ts [° C.] | 691 | 700 | 704 | 690 | 717 |
| 10^{6.0} dPa · s [° C.] | 822 | 835 | 842 | 803 | 843 |
| 10^{4.0} dPa · s [° C.] | 1,098 | 1,120 | 1,135 | 1,041 | 1,114 |
| 10^{3.0} dPa · s [° C.] | 1,331 | 1,366 | 1,396 | 1,262 | 1,367 |
| 10^{2.5} dPa · s [° C.] | 1,504 | 1,549 | 1,592 | 1,426 | 1,562 |
| TL [° C.] | 856 | 839 | 827 | 853 | 817 |
| logηTL [dPa · s] | 5.7 | 6.0 | 6.1 | 5.5 | 6.3 |
| Transmittance λ = 260 nm t = 0.5 mm | Unmeasured | Unmeasured | Unmeasured | 83.3 | 83.6 |
| Transmittance λ = 230 nm t = 0.5 mm | Unmeasured | Unmeasured | Unmeasured | 73.0 | 76.1 |
| Transmittance λ = 200 nm t = 0.5 mm | Unmeasured | Unmeasured | Unmeasured | 61.0 | 63.0 |
| T200/T260 | Unmeasured | Unmeasured | Unmeasured | 0.73 | 0.75 |
| Weather resistance | ∘ | ∘ | ∘ | ∘ | ∘ |

TABLE 2

| | | No. 11 | No. 12 | No. 13 | No. 14 | No. 15 | No. 16 |
|---|---|---|---|---|---|---|---|
| Composition | SiO₂ | 70.52 | 70.52 | 71.45 | 67.72 | 68.44 | 69.01 |
| (mass %) | Al₂O₃ | 6.25 | 5.95 | 5.15 | 5.21 | 3.57 | 3.30 |
| | B₂O₃ | 17.5 | 17.5 | 16.5 | 20.6 | 17.9 | 17.4 |
| | Li₂O | 0.75 | 0.95 | 0.00 | 0.80 | 0.21 | 0.16 |
| | Na₂O | 3.32 | 3.98 | 6.80 | 2.32 | 4.79 | 5.21 |
| | K₂O | 1.56 | 1.00 | 0.00 | 1.57 | 1.29 | 0.96 |
| | MgO | 0.00 | 0.00 | 0.00 | 0.00 | 0.36 | 0.27 |
| | CaO | 0.00 | 0.00 | 0.00 | 0.55 | 0.29 | 0.31 |
| | SrO | 0.00 | 0.00 | 0.00 | 0.00 | 0.43 | 0.32 |
| | BaO | 0.00 | 0.00 | 0.00 | 1.13 | 1.25 | 1.38 |
| | ZnO | 0.00 | 0.00 | 0.00 | 0.00 | 1.43 | 1.57 |
| | ZrO₂ | 0.00 | 0.00 | 0.00 | 0.00 | 0.00 | 0.00 |
| | TiO₂ | 0.00000 | 0.00000 | 0.00070 | 0.00005 | 0.00100 | 0.00080 |
| | F | 0.00 | 0.00 | 0.00 | 0.00 | 0.00 | 0.00 |
| | Cl | 0.100 | 0.10 | 0.10 | 0.10 | 0.10 | 0.10 |
| | SnO₂ | 0.00 | 0.00 | 0.00 | 0.00 | 0.00 | 0.00 |
| | Fe₂O₃ | 0.0010 | 0.0009 | 0.0009 | 0.0009 | 0.0010 | 0.0010 |

| | | | | | | |
|---|---|---|---|---|---|---|
| MgO + CaO + SrO + BaO | 0.00 | 0.00 | 0.00 | 1.68 | 2.32 | 2.28 |
| (MgO + CaO + SrO + Ba)/Al₂O₃ | 0.00 | 0.00 | 0.00 | 0.32 | 0.65 | 0.69 |
| B₂O₃ − (MgO + CaO + SrO + BaO) | 17.5 | 17.5 | 16.5 | 18.9 | 15.5 | 15.1 |
| (MgO + CaO + SrO + BaO)/(SiO₂ + | 0.000 | 0.000 | 0.000 | 0.018 | 0.026 | 0.025 |
| Al₂O₃ + B₂O₃) | | | | | | |
| B₂O₃ − Al₂O₃ | 11.3 | 11.6 | 11.4 | 15.4 | 14.3 | 14.1 |
| Li₂O + Na₂O + K₂O | 5.630 | 5.930 | 6.800 | 4.690 | 6.286 | 6.339 |
| Li₂O/(Li₂O + Na₂O + K₂O) | 0.133 | 0.160 | 0.000 | 0.171 | 0.034 | 0.025 |
| Na₂O/(Li₂O + Na₂O + K₂O) | 0.590 | 0.671 | 1.000 | 0.495 | 0.761 | 0.823 |
| K₂O/(Li₂O + Na₂O + K₂O) | 0.277 | 0.169 | 0.000 | 0.335 | 0.205 | 0.152 |
| TiO₂ + Fe₂O₃ | 0.00100 | 0.00090 | 0.00160 | 0.00095 | 0.00200 | 0.00180 |
| F + Cl + SnO₂ | 0.100 | 0.100 | 0.100 | 0.100 | 0.100 | 0.100 |
| ρ [g/cm³] | 2.22 | 2.23 | 2.24 | 2.22 | 2.31 | 2.31 |
| α [×10⁻⁷/° C.] | 42.7 | 43.8 | 45.5 | 40.8 | 45.3 | 45.5 |
| Ps [° C.] | 450 | 458 | 478 | 455 | 489 | 493 |
| Ta [° C.] | 497 | 501 | 523 | 500 | 528 | 533 |
| Ts [° C.] | 732 | 719 | 743 | 721 | 730 | 735 |
| 10^{6.0} dPa · s [° C.] | 866 | 841 | 859 | 841 | 839 | 842 |
| 10^{4.0} dPa · s [° C.] | 1,156 | 1,106 | 1,103 | 1,100 | 1,068 | 1,069 |
| 10^{3.0} dPa · s [° C.] | 1,422 | 1,354 | 1,326 | 1,348 | 1,283 | 1,279 |
| 10^{2.5} dPa · s [° C.] | 1,618 | 1,537 | 1,505 | 1,532 | 1,441 | 1,434 |
| TL [° C.] | 843 | 869 | 921 | 815 | 934 | 955 |
| logηTL [dPa · s] | 6.2 | 5.7 | 5.4 | 6.3 | 5.0 | 4.8 |
| Transmittance λ = 260 nm t = 0.5 mm | 84.1 | 85.5 | 85.8 | 84.6 | 84.0 | 84.2 |
| Transmittance λ = 230 nm t = 0.5 mm | 76.7 | 76.9 | 76.8 | 75.3 | 72.5 | 72.6 |
| Transmittance λ = 200 nm t = 0.5 mm | 64.6 | 65.5 | 65.8 | 62.3 | 52.8 | 49.8 |
| T200/T260 | 0.77 | 0.77 | 0.77 | 0.74 | 0.63 | 0.59 |
| Weather resistance | ∘ | ∘ | ∘ | ∘ | ∘ | ∘ |

| | | No. 17 | No. 18 | No. 19 | No. 20 |
|---|---|---|---|---|---|
| Composition | SiO₂ | 69.59 | 70.17 | 70.75 | 75.99 |
| (mass %) | Al₂O₃ | 3.04 | 2.77 | 2.50 | 1.67 |
| | B₂O₃ | 16.9 | 16.5 | 16.0 | 15.9 |
| | Li₂O | 0.11 | 0.05 | 0.00 | 1.22 |
| | Na₂O | 5.64 | 6.07 | 6.50 | 5.07 |
| | K₂O | 0.64 | 0.32 | 0.00 | 0.00 |
| | MgO | 0.18 | 0.09 | 0.00 | 0.00 |
| | CaO | 0.34 | 0.37 | 0.40 | 0.00 |
| | SrO | 0.21 | 0.11 | 0.00 | 0.00 |
| | BaO | 1.50 | 1.63 | 1.75 | 0.00 |
| | ZnO | 1.71 | 1.86 | 2.00 | 0.00 |
| | ZrO₂ | 0.00 | 0.00 | 0.00 | 0.00 |
| | TiO₂ | 0.00001 | 0.00050 | 0.00030 | 0.00000 |
| | F | 0.00 | 0.00 | 0.00 | 0.00 |
| | Cl | 0.10 | 0.10 | 0.10 | 0.103 |
| | SnO₂ | 0.00 | 0.00 | 0.00 | 0.00 |
| | Fe₂O₃ | 0.0010 | 0.0004 | 0.0001 | 0.0010 |

| | | | | |
|---|---|---|---|---|
| MgO + CaO + SrO + BaO | 2.24 | 2.19 | 2.15 | 0.00 |
| (MgO + CaO + SrO + Ba)/Al₂O₃ | 0.74 | 0.79 | 0.86 | 0.00 |
| B₂O₃ − (MgO + CaO + SrO + BaO) | 14.7 | 14.3 | 13.9 | 15.9 |
| (MgO + CaO + SrO + BaO)/(SiO₂ + | 0.025 | 0.025 | 0.024 | 0.000 |
| Al₂O₃ + B₂O₃) | | | | |
| B₂O₃ − Al₂O₃ | 13.9 | 13.7 | 13.5 | 14.3 |
| Li₂O + Na₂O + K₂O | 6.393 | 6.446 | 6.500 | 6.291 |
| Li₂O/(Li₂O + Na₂O + K₂O) | 0.017 | 0.008 | 0.000 | 0.194 |
| Na₂O/(Li₂O + Na₂O + K₂O) | 0.883 | 0.942 | 1.000 | 0.806 |
| K₂O/(Li₂O + Na₂O + K₂O) | 0.101 | 0.050 | 0.000 | 0.000 |
| TiO₂ + Fe₂O₃ | 0.00101 | 0.00090 | 0.00040 | 0.00100 |
| F + Cl + SnO₂ | 0.100 | 0.100 | 0.100 | 0.103 |
| ρ [g/cm³] | 2.32 | 2.33 | 2.34 | 2.27 |
| α [×10⁻⁷/° C.] | 46.0 | 46.1 | 46.2 | 44.8 |
| Ps [° C.] | 496 | 502 | 508 | 525 |
| Ta [° C.] | 535 | 541 | 547 | 562 |
| Ts [° C.] | 735 | 741 | 745 | 744 |
| 10^{6.0} dPa · s [° C.] | 842 | 845 | 849 | 841 |
| 10^{4.0} dPa · s [° C.] | 1,066 | 1,064 | 1,065 | 1,052 |
| 10^{3.0} dPa · s [° C.] | 1,272 | 1,267 | 1,265 | 1,262 |
| 10^{2.5} dPa · s [° C.] | 1,425 | 1,414 | 1,415 | 1,415 |
| TL [° C.] | 985 | >1,009 | >1,005 | 1,075 |
| logηTL [dPa · s] | 4.6 | <4.4 | <4.4 | 3.9 |
| Transmittance λ = 260 nm t = 0.5 mm | 83.9 | 84.0 | 84.0 | 82.2 |
| Transmittance λ = 230 nm t = 0.5 mm | 72.2 | 72.0 | 71.9 | 72.5 |
| Transmittance λ = 200 nm t = 0.5 mm | 47.3 | 43.2 | 39.3 | 64.3 |
| T200/T260 | 0.56 | 0.51 | 0.47 | 0.78 |
| Weather resistance | ∘ | ∘ | ∘ | Unmeasured |

TABLE 3

| | | No. 21 | No. 22 | No. 23 | No. 24 | No. 25 |
|---|---|---|---|---|---|---|
| Composition | SiO₂ | 73.80 | 71.62 | 69.45 | 67.29 | 73.03 |
| (mass %) | Al₂O₃ | 1.66 | 1.66 | 1.65 | 1.65 | 4.94 |
| | B₂O₃ | 18.2 | 20.4 | 22.6 | 24.7 | 15.7 |
| | Li₂O | 1.22 | 1.21 | 1.21 | 1.21 | 1.21 |
| | Na₂O | 5.05 | 5.04 | 5.02 | 5.01 | 5.00 |
| | K₂O | 0.00 | 0.00 | 0.00 | 0.00 | 0.00 |
| | MgO | 0.00 | 0.00 | 0.00 | 0.00 | 0.00 |
| | CaO | 0.00 | 0.00 | 0.00 | 0.00 | 0.00 |
| | SrO | 0.00 | 0.00 | 0.00 | 0.00 | 0.00 |
| | BaO | 0.00 | 0.00 | 0.00 | 0.00 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00000 | 0.00000 | 0.00000 | 0.00000 | 0.00000 |
| | F | 0.00 | 0.00 | 0.00 | 0.00 | 0.00 |
| | Cl | 0.103 | 0.102 | 0.102 | 0.102 | 0.102 |
| | SnO₂ | 0.00 | 0.00 | 0.00 | 0.00 | 0.00 |
| | Fe₂O₃ | 0.0010 | 0.0005 | 0.0010 | 0.0010 | 0.0010 |
| MgO + CaO + SrO + BaO | | 0.00 | 0.00 | 0.00 | 0.00 | 0.00 |
| (MgO + CaO + SrO + Ba)/Al₂O₃ | | 0.00 | 0.00 | 0.00 | 0.00 | 0.00 |
| B₂O₃ − (MgO + CaO + SrO + BaO) | | 18.2 | 20.4 | 22.6 | 24.7 | 15.7 |
| (MgO + CaO + SrO + BaO)/(SiO₂ + | | 0.000 | 0.000 | 0.000 | 0.000 | 0.000 |
| Al ₂O₃ + B₂O₃) | | | | | | |
| B₂O₃ − Al₂O₃ | | 16.5 | 18.7 | 20.9 | 23.1 | 10.8 |
| Li₂O + Na₂O + K₂O | | 6.272 | 6.252 | 6.233 | 6.214 | 6.206 |
| Li₂O/(Li₂O + Na₂O + K₂O) | | 0.194 | 0.194 | 0.194 | 0.194 | 0.194 |
| Na₂O/(Li₂O + Na₂O + K₂O) | | 0.806 | 0.806 | 0.806 | 0.806 | 0.806 |
| K₂O/(Li₂O + Na₂O + K₂O) | | 0.000 | 0.000 | 0.000 | 0.000 | 0.000 |
| TiO₂ + Fe₂O₃ | | 0.00100 | 0.00050 | 0.00100 | 0.00100 | 0.00100 |
| F + Cl + SnO₂ | | 0.103 | 0.102 | 0.102 | 0.102 | 0.102 |
| ρ [g/cm³] | | 2.25 | 2.23 | 2.22 | 2.21 | 2.26 |
| α [×10⁻⁷/° C.] | | 43.6 | 44.2 | 41.8 | 41.2 | 41.5 |
| Ps [° C.] | | 521 | 523 | 521 | 524 | 484 |
| Ta [° C.] | | 557 | 561 | 562 | 569 | 523 |
| Ts [° C.] | | 743 | 743 | 743 | 740 | 719 |
| 10^{6.0} dPa · s [° C.] | | 834 | 829 | 822 | 814 | 833 |
| 10^{4.0} dPa · s [° C.] | | 1,028 | 1,009 | 986 | 970 | 1,081 |
| 10^{3.0} dPa · s [° C.] | | 1,228 | 1,203 | 1,173 | 1,152 | 1,306 |
| 10^{2.5} dPa · s [° C.] | | 1,369 | 1,344 | 1,308 | 1,283 | 1,466 |
| TL [° C.] | | 1,008 | 983 | 919 | 885 | 993 |
| logηTL [dPa · s] | | 4.2 | 4.2 | 4.7 | 4.9 | 4.6 |
| Transmittance λ = 260 nm t = 0.5 mm | | 83.3 | 82.6 | 83.5 | 80.3 | 87.7 |
| Transmittance λ = 230 nm t = 0.5 mm | | 74.3 | 73.2 | 74.9 | 72.4 | 81.7 |
| Transmittance λ = 200 nm t = 0.5 mm | | 66.0 | 64.6 | 65.1 | 59.1 | 71.8 |
| T200/T260 | | 0.79 | 0.78 | 0.78 | 0.74 | 0.82 |
| Weather resistance | | Unmeasured | Unmeasured | Unmeasured | Unmeasured | Unmeasured |
| | | No. 26 | No. 27 | No. 28 | No. 29 | No. 30 |
| Composition | SiO₂ | 70.87 | 68.73 | 66.60 | 64.48 | 70.14 |
| (mass %) | Al₂O₃ | 4.92 | 4.91 | 4.89 | 4.88 | 8.12 |
| | B₂O₃ | 17.9 | 20.1 | 22.3 | 24.4 | 15.5 |
| | Li₂O | 1.20 | 1.20 | 1.19 | 1.19 | 1.19 |
| | Na₂O | 4.99 | 4.97 | 4.96 | 4.94 | 4.93 |
| | K₂O | 0.00 | 0.00 | 0.00 | 0.00 | 0.00 |
| | MgO | 0.00 | 0.00 | 0.00 | 0.00 | 0.00 |
| | CaO | 0.00 | 0.00 | 0.00 | 0.00 | 0.00 |
| | SrO | 0.00 | 0.00 | 0.00 | 0.00 | 0.00 |
| | BaO | 0.00 | 0.00 | 0.00 | 0.00 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00010 | 0.00000 | 0.00000 | 0.00100 | 0.00000 |
| | F | 0.00 | 0.00 | 0.00 | 0.00 | 0.00 |
| | Cl | 0.101 | 0.101 | 0.101 | 0.100 | 0.100 |
| | SnO₂ | 0.00 | 0.00 | 0.00 | 0.00 | 0.00 |
| | Fe₂O₃ | 0.0000 | 0.0010 | 0.0010 | 0.0010 | 0.0010 |

| | | | | | |
|---|---|---|---|---|---|
| MgO + CaO + SrO + BaO | 0.00 | 0.00 | 0.00 | 0.00 | 0.00 |
| (MgO + CaO + SrO + Ba)/Al₂O₃ | 0.00 | 0.00 | 0.00 | 0.00 | 0.00 |
| B₂O₃ − (MgO + CaO + SrO + BaO) | 17.9 | 20.1 | 22.3 | 24.4 | 15.5 |
| (MgO + CaO + SrO + BaO)/(SiO₂ + | 0.000 | 0.000 | 0.000 | 0.000 | 0.000 |
| Al ₂O₃ + B₂O₃) | | | | | |
| B₂O₃ − Al₂O₃ | 13.0 | 15.2 | 17.4 | 19.5 | 7.4 |
| Li₂O + Na₂O + K₂O | 6.187 | 6.168 | 6.149 | 6.131 | 6.123 |
| Li₂O/(Li₂O + Na₂O + K₂O) | 0.194 | 0.194 | 0.194 | 0.194 | 0.194 |
| Na₂O/(Li₂O + Na₂O + K₂O) | 0.806 | 0.806 | 0.806 | 0.806 | 0.806 |
| K₂O/(Li₂O + Na₂O + K₂O) | 0.000 | 0.000 | 0.000 | 0.000 | 0.000 |
| TiO₂ + Fe₂O₃ | 0.00010 | 0.00100 | 0.00100 | 0.00200 | 0.00100 |
| F + Cl + SnO₂ | 0.101 | 0.101 | 0.101 | 0.100 | 0.100 |
| ρ [g/cm³] | 2.25 | 2.23 | 2.22 | 2.21 | 2.25 |
| α [×10⁻⁷/° C.] | 41.0 | 41.5 | 41.8 | 43.1 | 44.8 |
| Ps [° C.] | 476 | 466 | 456 | 447 | 476 |
| Ta [° C.] | 515 | 505 | 494 | 486 | 519 |
| Ts [° C.] | 708 | 697 | 684 | 675 | 732 |
| 10^{6.0} dPa · s [° C.] | 817 | 802 | 788 | 778 | 860 |
| 10^{4.0} dPa · s [° C.] | 1,053 | 1,028 | 1,009 | 997 | 1,140 |
| 10^{3.0} dPa · s [° C.] | 1,271 | 1,237 | 1,212 | 1,194 | 1,390 |
| 10^{2.5} dPa · s [° C.] | 1,424 | 1,385 | 1,357 | 1,336 | 1,555 |
| TL [° C.] | 962 | 904 | 834 | 798 | 872 |
| logηTL [dPa · s] | 4.6 | 4.9 | 5.5 | 5.8 | 5.9 |
| Transmittance λ = 260 nm t = 0.5 mm | 86.8 | 84.6 | 83.7 | 85.6 | 82.6 |
| Transmittance λ = 230 nm t = 0.5 mm | 80.8 | 78.7 | 78.4 | 80.1 | 78.2 |
| Transmittance λ = 200 nm t = 0.5 mm | 73.4 | 71.9 | 72.4 | 73.1 | 71.2 |
| T200/T260 | 0.85 | 0.85 | 0.86 | 0.85 | 0.86 |
| Weather resistance | Unmeasured | Unmeasured | Unmeasured | Unmeasured | Unmeasured |

TABLE 4

| | | No. 31 | No . 32 | No. 33 | No. 34 | No. 35 |
|---|---|---|---|---|---|---|
| Composition | SiO₂ | 68.02 | 65.91 | 63.82 | 61.74 | 73.99 |
| (mass %) | Al₂O₃ | 8.09 | 8.07 | 8.04 | 8.02 | 5.00 |
| | B₂O₃ | 17.7 | 19.8 | 22.0 | 24.1 | 15.9 |
| | Li₂O | 1.19 | 1.18 | 1.18 | 1.18 | 2.44 |
| | Na₂O | 4.92 | 4.90 | 4.89 | 4.87 | 2.53 |
| | K₂O | 0.00 | 0.00 | 0.00 | 0.00 | 0.00 |
| | MgO | 0.00 | 0.00 | 0.00 | 0.00 | 0.00 |
| | CaO | 0.00 | 0.00 | 0.00 | 0.00 | 0.00 |
| | SrO | 0.00 | 0.00 | 0.00 | 0.00 | 0.00 |
| | BaO | 0.00 | 0.00 | 0.00 | 0.00 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00000 | 0.00000 | 0.00000 | 0.00000 | 0.00000 |
| | F | 0.00 | 0.00 | 0.00 | 0.00 | 0.00 |
| | Cl | 0.100 | 0.100 | 0.099 | 0.099 | 0.103 |
| | SnO₂ | 0.00 | 0.00 | 0.00 | 0.00 | 0.00 |
| | Fe₂O3 | 0.0010 | 0.0005 | 0.0010 | 0.0010 | 0.0010 |
| MgO + CaO + SrO + BaO | | 0.00 | 0.00 | 0.00 | 0.00 | 0.00 |
| (MgO + CaO + SrO + Ba)/Al₂O₃ | | 0.00 | 0.00 | 0.00 | 0.00 | 0.00 |
| B₂O₃ − (MgO + CaO + SrO + BaO) | | 17.7 | 19.8 | 22.0 | 24.1 | 15.9 |
| (MgO + CaO + SrO + BaO)/(SiO₂ + | | 0.000 | 0.000 | 0.000 | 0.000 | 0.000 |
| Al ₂O₃ + B₂O₃) | | | | | | |
| B₂O₃ − Al₂O₃ | | 9.6 | 11.8 | 13.9 | 16.1 | 10.9 |
| Li₂O + Na₂O + K₂O | | 6.105 | 6.087 | 6.068 | 6.050 | 4.976 |
| Li₂O/(Li₂O + Na₂O + K₂O) | | 0.194 | 0.194 | 0.194 | 0.194 | 0.491 |
| Na₂O/(Li₂O + Na₂O + K₂O) | | 0.806 | 0.806 | 0.806 | 0.806 | 0.509 |
| K₂O/(Li₂O + Na₂O + K₂O) | | 0.000 | 0.000 | 0.000 | 0.000 | 0.000 |
| TiO₂ + Fe₂O₃ | | 0.00100 | 0.00050 | 0.00100 | 0.00100 | 0.00100 |
| F + Cl + SnO₂ | | 0.100 | 0.100 | 0.099 | 0.099 | 0.103 |
| ρ [g/cm³] | | 2.24 | 2.23 | 2.22 | 2.21 | 2.24 |
| α [×10⁻⁷/° C.] | | 43.6 | 44.2 | 41.8 | 41.2 | 44.8 |
| Ps [° C.] | | 465 | 454 | 445 | 436 | 491 |
| Ta [° C.] | | 508 | 496 | 486 | 476 | 529 |
| Ts [° C.] | | 716 | 701 | 687 | 670 | 717 |
| 10^{6.0} dPa · s [° C.] | | 842 | 821 | 800 | 784 | 829 |
| 10^{4.0} dPa · s [° C.] | | 1,116 | 1,082 | 1,046 | 1,032 | 1,079 |
| 10^{3.0} dPa · s [° C.] | | 1,360 | 1,320 | 1,273 | 1,253 | 1,313 |
| 10^{2.5} dPa · s [° C.] | | 1,529 | 1,482 | 1,432 | 1,410 | 1,476 |
| TL [° C.] | | 798 | <777 | <791 | <791 | 1,038 |
| logηTL [dPa · s] | | 6.5 | >6.5 | >6.1 | >5.9 | 4.2 |
| Transmittance λ = 260 nm t = 0.5 mm | | 85.2 | 82.6 | 86.7 | 84.7 | 85.5 |
| Transmittance λ = 230 nm t = 0.5 mm | | 79.6 | 76.4 | 81.9 | 80.4 | 78.7 |
| Transmittance λ = 200 nm t = 0.5 mm | | 73.3 | 71.0 | 75.5 | 74.3 | 71.5 |
| T200/T260 | | 0.86 | 0.86 | 0.87 | 0.88 | 0.84 |
| Weather resistance | | Unmeasured | Unmeasured | Unmeasured | Unmeasured | Unmeasured |
| | | No. 36 | No. 37 | No. 38 | No. 39 | No. 40 |
| Composition | SiO₂ | 71.80 | 69.62 | 67.46 | 65.31 | 71.05 |
| (mass %) | Al₂O₃ | 4.99 | 4.97 | 4.95 | 4.94 | 8.22 |
| | B₂O₃ | 18.2 | 20.4 | 22.6 | 24.7 | 15.7 |
| | Li₂O | 2.43 | 2.43 | 2.42 | 2.41 | 2.41 |
| | Na₂O | 2.53 | 2.52 | 2.51 | 2.50 | 2.50 |
| | K₂O | 0.00 | 0.00 | 0.00 | 0.00 | 0.00 |
| | MgO | 0.00 | 0.00 | 0.00 | 0.00 | 0.00 |
| | CaO | 0.00 | 0.00 | 0.00 | 0.00 | 0.00 |
| | SrO | 0.00 | 0.00 | 0.00 | 0.00 | 0.00 |
| | BaO | 0.00 | 0.00 | 0.00 | 0.00 | 0.00 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00000 | 0.00000 | 0.00000 | 0.00000 | 0.00000 |
| | F | 0.00 | 0.00 | 0.00 | 0.00 | 0.00 |
| | Cl | 0.103 | 0.102 | 0.102 | 0.102 | 0.101 |
| | SnO₂ | 0.00 | 0.00 | 0.00 | 0.00 | 0.00 |
| | Fe₂O3 | 0.0010 | 0.0005 | 0.0010 | 0.0010 | 0.0010 |

| | | | | | |
|---|---|---|---|---|---|
| MgO + CaO + SrO + BaO | 0.00 | 0.00 | 0.00 | 0.00 | 0.00 |
| (MgO + CaO + SrO + Ba)/Al₂O₃ | 0.00 | 0.00 | 0.00 | 0.00 | 0.00 |
| B₂O₃ − (MgO + CaO + SrO + BaO) | 18.2 | 20.4 | 22.6 | 24.7 | 15.7 |
| (MgO + CaO + SrO + BaO)/(SiO₂ + | 0.000 | 0.000 | 0.000 | 0.000 | 0.000 |
| Al ₂O₃ + B₂O₃) | | | | | |
| B₂O₃ − Al₂O₃ | 13.2 | 15.4 | 17.6 | 19.8 | 7.5 |
| Li₂O + Na₂O + K₂O | 4.960 | 4.945 | 4.930 | 4.914 | 4.909 |
| Li₂O/(Li₂O + Na₂O + K₂O) | 0.491 | 0.491 | 0.491 | 0.491 | 0.491 |
| Na₂O/(Li₂O + Na₂O + K₂O) | 0.509 | 0.509 | 0.509 | 0.509 | 0.509 |
| K₂O/(Li₂O + Na₂O + K₂O) | 0.000 | 0.000 | 0.000 | 0.000 | 0.000 |
| TiO₂ + Fe₂O₃ | 0.00100 | 0.00050 | 0.00100 | 0.00100 | 0.00100 |
| F + Cl + SnO₂ | 0.103 | 0.102 | 0.102 | 0.102 | 0.101 |
| ρ [g/cm³] | 2.23 | 2.22 | 2.20 | 2.20 | 2.24 |
| α [×10⁻⁷/° C.] | 43.6 | 44.2 | 41.8 | 41.2 | 41.5 |
| Ps [° C.] | 487 | 477 | 467 | 460 | 478 |
| Ta [° C.] | 524 | 514 | 504 | 497 | 519 |
| Ts [° C.] | 707 | 699 | 691 | 683 | 726 |
| 10^{6.0} dPa · s [° C.] | 815 | 803 | 793 | 778 | 850 |
| 10^{4.0} dPa · s [° C.] | 1,055 | 1,033 | 1,013 | 978 | 1,127 |
| 10^{3.0} dPa · s [° C.] | 1,284 | 1,255 | 1,226 | 1,173 | 1,380 |
| 10^{2.5} dPa · s [° C.] | 1,443 | 1,411 | 1,375 | 1,314 | 1,549 |
| TL [° C.] | 966 | 910 | 887 | 820 | 1,009 |
| logηTL [dPa · s] | 4.6 | 4.9 | 5.0 | 5.5 | 4.7 |
| Transmittance λ = 260 nm t = 0.5 mm | 86.9 | 83.3 | 84.7 | 88.8 | 89.4 |
| Transmittance λ = 230 nm t = 0.5 mm | 81.2 | 78.0 | 78.4 | 84.5 | 85.4 |
| Transmittance λ = 200 nm t = 0.5 mm | 73.2 | 69.5 | 69.4 | 74.2 | 75.2 |
| T200/T260 | 0.84 | 0.84 | 0.82 | 0.84 | 0.84 |
| Weather resistance | Unmeasured | Unmeasured | Unmeasured | Unmeasured | Unmeasured |

TABLE 5

| | | No. 41 | No. 42 | No. 43 | No. 44 | No. 45 |
|---|---|---|---|---|---|---|
| Composition | SiO₂ | 68.90 | 66.76 | 64.64 | 62.53 | 66.99 |
| (mass %) | Al₂O₃ | 8.20 | 8.17 | 8.15 | 8.12 | 5.21 |
| | B₂O₃ | 17.9 | 20.1 | 22.3 | 24.4 | 20.6 |
| | Li₂O | 2.40 | 2.39 | 2.39 | 2.38 | 0.80 |
| | Na₂O | 2.49 | 2.48 | 2.48 | 2.47 | 2.32 |
| | K₂O | 0.00 | 0.00 | 0.00 | 0.00 | 1.57 |
| | MgO | 0.00 | 0.00 | 0.00 | 0.00 | 0.00 |
| | CaO | 0.00 | 0.00 | 0.00 | 0.00 | 0.55 |
| | SrO | 0.00 | 0.00 | 0.00 | 0.00 | 0.00 |
| | BaO | 0.00 | 0.00 | 0.00 | 0.00 | 1.13 |
| | ZnO | 0.00 | 0.00 | 0.00 | 0.00 | 0.00 |
| | ZrO₂ | 0.00 | 0.00 | 0.00 | 0.00 | 0.00 |
| | TiO₂ | 0.00010 | 0.00000 | 0.00000 | 0.00100 | 0.00000 |
| | F | 0.00 | 0.00 | 0.00 | 0.00 | 0.75 |
| | Cl | 0.101 | 0.101 | 0.101 | 0.100 | 0.085 |
| | SnO₂ | 0.00 | 0.00 | 0.00 | 0.00 | 0.00 |
| | Fe₂O₃ | 0.0000 | 0.0010 | 0.0010 | 0.0010 | 0.0010 |

| | | | | | |
|---|---|---|---|---|---|
| MgO + CaO + SrO + BaO | 0.00 | 0.00 | 0.00 | 0.00 | 1.68 |
| (MgO + CaO + SrO + Ba)/Al₂O₃ | 0.00 | 0.00 | 0.00 | 0.00 | 0.32 |
| B₂O₃ − (MgO + CaO + SrO + BaO) | 17.9 | 20.1 | 22.3 | 24.4 | 18.9 |
| (MgO + CaO + SrO + BaO)/(SiO₂ + | 0.000 | 0.000 | 0.000 | 0.000 | 0.018 |
| Al₂ O₃ + B₂O₃) | | | | | |
| B₂O₃ − Al₂O₃ | 9.7 | 11.9 | 14.1 | 16.3 | 15.4 |
| Li₂O + Na₂O + K₂O | 4.893 | 4.879 | 4.864 | 4.849 | 4.690 |
| Li₂O/(Li₂O + Na₂O + K₂O) | 0.491 | 0.491 | 0.491 | 0.491 | 0.171 |
| Na₂O/(Li₂O + Na₂O + K₂O) | 0.509 | 0.509 | 0.509 | 0.509 | 0.495 |
| K₂O/(Li₂O + Na₂O + K₂O) | 0.000 | 0.000 | 0.000 | 0.000 | 0.335 |
| TiO₂ + Fe₂O₃ | 0.00010 | 0.00100 | 0.00100 | 0.00200 | 0.00100 |
| F + Cl + SnO₂ | 0.101 | 0.101 | 0.101 | 0.100 | 0.835 |
| ρ [g/cm³] | 2.23 | 2.22 | 2.21 | 2.20 | 2.22 |
| α [×10⁻⁷/° C.] | 41.0 | 41.5 | 41.8 | 43.1 | 44.8 |
| Ps [° C.] | 467 | 458 | 449 | 440 | 430 |
| Ta [° C.] | 508 | 498 | 488 | 480 | 476 |
| Ts [° C.] | 707 | 693 | 679 | 667 | 700 |
| 10^{6.0} dPa · s [° C.] | 831 | 811 | 791 | 770 | 821 |
| 10^{4.0} dPa · s [° C.] | 1,106 | 1,073 | 1,039 | 995 | 1,080 |
| 10^{3.0} dPa · s [° C.] | 1,352 | 1,314 | 1,270 | 1,216 | 1,326 |
| 10^{2.5} dPa · s [° C.] | 1,505 | 1,473 | 1,425 | 1,372 | 1,502 |
| TL [° C.] | 886 | <791 | <791 | <791 | Unmeasured |
| logηTL [dPa · s] | 5.5 | >6.2 | >6.0 | >5.7 | Unmeasured |
| Transmittance λ = 260 nm t = 0.5 mm | 90.4 | 89.7 | 86.8 | 90.3 | 89.7 |
| Transmittance λ = 230 nm t = 0.5 mm | 86.8 | 86.0 | 83.6 | 87.0 | 85.0 |
| Transmittance λ = 200 nm t = 0.5 mm | 77.1 | 76.8 | 74.7 | 78.1 | 72.4 |
| T200/T260 | 0.85 | 0.86 | 0.86 | 0.87 | 0.81 |
| Weather resistance | ∘ | Unmeasured | Unmeasured | Unmeasured | Unmeasured |

| | | No. 46 | No. 47 | No. 48 | No. 49 | No. 50 |
|---|---|---|---|---|---|---|
| Composition | SiO₂ | 79.19 | 59.76 | 57.10 | 57.86 | 59.75 |
| (mass %) | Al₂O₃ | 2.32 | 12.11 | 15.14 | 5.71 | 6.25 |
| | B₂O₃ | 14.1 | 24.3 | 23.9 | 21.6 | 22.5 |
| | Li₂O | 0.00 | 3.34 | 3.29 | 0.86 | 1.00 |
| | Na₂O | 4.39 | 0.44 | 0.44 | 1.36 | 0.50 |
| | K₂O | 0.00 | 0.00 | 0.00 | 3.86 | 4.50 |
| | MgO | 0.00 | 0.00 | 0.00 | 2.57 | 2.50 |
| | CaO | 0.00 | 0.00 | 0.00 | 0.11 | 0.00 |
| | SrO | 0.00 | 1.68 | 0.00 | 3.00 | 3.00 |
| | BaO | 0.00 | 0.00 | 0.00 | 0.57 | 0.00 |
| | ZnO | 0.00 | 0.00 | 0.00 | 0.71 | 0.00 |
| | ZrO₂ | 0.00 | 0.00 | 0.00 | 0.00 | 0.04 |
| | TiO₂ | 0.00000 | 0.00000 | 0.00000 | 0.00020 | 0.00070 |
| | F | 0.00 | 0.00 | 0.00 | 1.71 | 0.00 |
| | Cl | 0.100 | 0.101 | 0.100 | 0.10 | 0.00 |
| | SnO₂ | 0.00 | 0.00 | 0.00 | 0.00 | 0.000 |
| | Fe₂O₃ | 0.0010 | 0.0005 | 0.0010 | 0.0007 | 0.0000 |

| | | | | | |
|---|---|---|---|---|---|
| MgO + CaO + SrO + BaO | 0.00 | 1.68 | 0.00 | 6.26 | 5.50 |
| (MgO + CaO + SrO + Ba)/Al₂O₃ | 0.00 | 0.14 | 0.00 | 1.10 | 0.88 |
| B₂O₃ − (MgO + CaO + SrO + BaO) | 14.1 | 22.6 | 23.9 | 15.3 | 17.0 |
| (MgO + CaO + SrO + BaO)/(SiO₂ + | 0.000 | 0.017 | 0.000 | 0.073 | 0.062 |
| Al₂ O₃ + B₂O₃) | | | | | |
| B₂O₃ − Al₂O₃ | 11.8 | 12.1 | 8.8 | 15.9 | 16.3 |
| Li₂O + Na₂O + K₂O | 4.390 | 3.777 | 3.728 | 6.071 | 6.000 |
| Li₂O/(Li₂O + Na₂O + K₂O) | 0.000 | 0.883 | 0.883 | 0.141 | 0.167 |
| Na₂O/(Li₂O + Na₂O + K₂O) | 1.000 | 0.117 | 0.117 | 0.224 | 0.083 |
| K₂O/(Li₂O + Na₂O + K₂O) | 0.000 | 0.000 | 0.000 | 0.635 | 0.750 |
| TiO₂ + Fe₂O₃ | 0.00100 | 0.00050 | 0.00100 | 0.00090 | 0.00070 |
| F + Cl + SnO₂ | 0.100 | 0.101 | 0.100 | 1.814 | 0.000 |
| ρ [g/cm³] | 2.22 | Unmeasured | Unmeasured | Phase | Phase |
| | | | | separation | separation |
| α [×10⁻⁷/° C.] | 43.6 | 44.2 | 41.8 | Phase | Phase |
| | | | | separation | separation |
| Ps [° C.] | 506 | Unmeasured | Unmeasured | Phase | Phase |
| | | | | separation | separation |
| Ta [° C.] | 554 | 467 | 450 | Phase | Phase |
| | | | | separation | separation |
| Ts [° C.] | 798 | Unmeasured | Unmeasured | Phase | Phase |
| | | | | separation | separation |
| 10^{6.0} dPa · s [° C.] | 931 | Unmeasured | Unmeasured | Phase | Phase |
| | | | | separation | separation |
| 10^{4.0} dPa · s [° C.] | 1,214 | Unmeasured | Unmeasured | Phase | Phase |
| | | | | separation | separation |
| 10^{3.0} dPa · s [° C.] | 1,472 | Unmeasured | Unmeasured | Phase | Phase |
| | | | | separation | separation |
| 10^{2.5} dPa · s [° C.] | 1,651 | 1,413 | 1,474 | Phase | Phase |
| | | | | separation | separation |
| TL [° C.] | Unmeasured | Unmeasured | Unmeasured | Phase | Phase |
| | | | | separation | separation |
| logηTL [dPa · s] | Unmeasured | Unmeasured | Unmeasured | Phase | Phase |
| | | | | separation | separation |
| Transmittance λ = 260 nm t = 0.5 mm | 86.4 | 90.1 | 89.8 | Phase | Phase |
| | | | | separation | separation |
| Transmittance λ = 230 nm t = 0.5 mm | 80.0 | 86.7 | 86.1 | Phase | Phase |
| | | | | separation | separation |
| Transmittance λ = 200 nm t = 0.5 mm | 72.4 | 81.0 | 81.8 | Phase | Phase |
| | | | | separation | separation |
| T200/T260 | 0.84 | 0.90 | 0.91 | Phase | Phase |
| | | | | separation | separation |
| Weather resistance | Unmeasured | Unmeasured | Unmeasured | x | x |

TABLE 6

| | | No. 51 | No. 52 |
|---|---|---|---|
| Composition | SiO₂ | 60.21 | 60.67 |
| (mass %) | Al₂O₃ | 5.98 | 5.71 |
| | B₂O₃ | 22.0 | 21.6 |
| | Li₂O | 0.93 | 0.86 |
| | Na₂O | 0.93 | 1.36 |
| | K₂O | 4.18 | 3.86 |
| | MgO | 2.32 | 2.14 |
| | CaO | 0.06 | 0.11 |
| | SrO | 2.79 | 2.57 |
| | BaO | 0.25 | 0.50 |
| | ZnO | 0.29 | 0.57 |
| | ZrO₂ | 0.07 | 0.08 |
| | TiO₂ | 0.00000 | 0.00000 |
| | F | 0.00 | 0.00 |
| | Cl | 0.04 | 0.07 |
| | SnO₂ | 0.000 | 0.000 |
| | Fe₂O₃ | 0.0005 | 0.0001 |

| | | |
|---|---|---|
| MgO + CaO + SrO + BaO | 5.41 | 5.33 |
| (MgO + CaO + SrO + Ba)/Al₂O₃ | 0.91 | 0.93 |
| B₂O₃ − (MgO + CaO + SrO + BaO) | 16.6 | 16.2 |
| (MgO + CaO + SrO + BaO)/(SiO₂ + | 0.061 | 0.061 |
| Al₂O₃ + B₂O₃) | | |
| B₂O₃ − Al₂O₃ | 16.1 | 15.9 |
| Li₂O + Na₂O + K₂O | 6.036 | 6.071 |
| Li₂O/(Li₂O + Na₂O + K₂O) | 0.154 | 0.141 |
| Na₂O/(Li₂O + Na₂O + K₂O) | 0.154 | 0.224 |
| K₂O/(Li₂O + Na₂O + K₂O) | 0.692 | 0.635 |
| TiO₂ + Fe₂O₃ | 0.00050 | 0.00010 |
| F + Cl + SnO₂ | 0.036 | 0.071 |
| ρ [g/cm³] | Phase | Phase |
| | separation | separation |
| α [×10⁻⁷/° C.] | Phase | Phase |
| | separation | separation |
| Ps [° C.] | Phase | Phase |
| | separation | separation |
| Ta [° C.] | Phase | Phase |
| | separation | separation |
| Ts [° C.] | Phase | Phase |
| | separation | separation |
| 10^{6.0} dPa · s [° C.] | Phase | Phase |
| | separation | separation |
| 10^{4.0} dPa · s [° C.] | Phase | Phase |
| | separation | separation |
| 10^{3.0} dPa · s [° C.] | Phase | Phase |
| | separation | separation |
| 10^{2.5} dPa · s [° C.] | Phase | Phase |
| | separation | separation |
| TL [° C.] | Phase | Phase |
| | separation | separation |
| logηTL [dPa · s] | Phase | Phase |
| | separation | separation |
| Transmittance λ = 260 nm t = 0.5 mm | Phase | Phase |
| | separation | separation |
| Transmittance λ = 230 nm t = 0.5 mm | Phase | Phase |
| | separation | separation |
| Transmittance λ = 200 nm t = 0.5 mm | Phase | Phase |
| | separation | separation |
| T200/T260 | Phase | Phase |
| | separation | separation |
| Weather resistance | x | x |

First, a glass batch prepared by blending glass raw materials shown in the tables so that each glass composition listed in the tables was attained was placed in a platinum crucible and melted at 1,650° C. for 4 hours. Aluminum fluoride was used as a raw material for introducing F.

The resultant molten glass was stirred to be homogenized by using a platinum stirrer. Next, the molten glass was poured out on a carbon sheet and formed into a flat sheet shape, followed by annealing from a temperature higher than the annealing point by about 20° C. to room temperature at a rate of 3° C/min.

The density ρ was measured by a well-known Archimedes method. The average thermal expansion coefficient a in a range of from 30° C. to 380° C. was measured with a dilatometer.

The strain point Ps, the annealing point Ta, the softening point Ts, the temperature corresponding to glass viscosity Logp=4.0 dPa·s (10^{4.0} dPa·s), the temperature corresponding to glass viscosity Logp=3.0 dPa·s (10^{3.0} dPa·s), and the temperature corresponding to glass viscosity Logp=2.5 dPa·s (10^{3.0} dPa·s) are each a value measured by a well-known method, such as a platinum sphere pull up method. In addition, the temperature corresponding to glass viscosity Logρ=6.0 dPa·s (10^{6.0} dPa·s) was determined through calculation by substituting the above-mentioned glass viscosity into the Fulcher equation.

The liquidus temperature TL is a temperature at which a crystal precipitates after glass powder that passes through a standard 30-mesh sieve (500 pm) and remains on a 50-mesh sieve (300 pm) is placed in a platinum boat and kept in a gradient heating furnace for 24 hours. The glass viscosity logηTL at the liquidus temperature is a value obtained by measuring the viscosity of glass at its liquidus temperature TL by the platinum sphere pull up method.

The external transmittance is a value obtained by measuring a spectral transmittance in a thickness direction through use of a double-beam spectrophotometer. Each of measurement samples used had a thickness of 0.5 mm, and had both surfaces thereof polished into optically polished surfaces (mirror surfaces). The surface roughness Ra of the glass surface of each of those measurement samples was measured by AFM, and as a result, was found to be from 0.5 nm to 1.0 nm in a measurement area of 5 μm×5 μm.

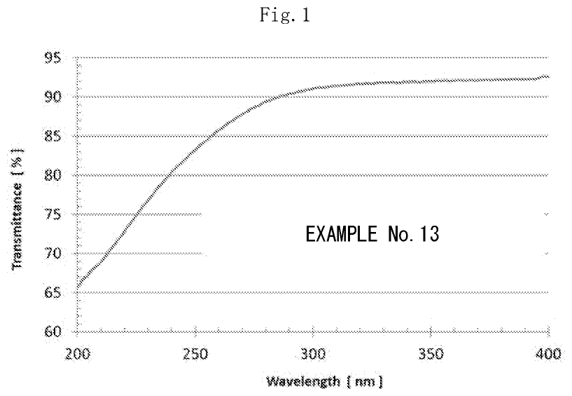

FIG. 1 is a transmittance curve of Sample No. 13 having a thickness of 0.5 mm in the wavelength range of from 200 nm to 400 nm.

Each obtained sample was evaluated for its weather resistance. First, each glass was subjected to lapping processing so as to have dimensions of 20 mm×35 mm×2.03 mm, and then subjected to polishing processing so as to have dimensions of 20 mm×35 mm×2.00 mm, to thereby process the glass surface into a mirror surface. In order to check the weather resistance, a highly accelerated stress test (HAST) was performed at a temperature of 121° C. and a relative humidity of 85% for a test time of 24 hours. A test apparatus manufactured by Hirayama Manufacturing Corporation was used for the highly accelerated stress test. In the observation of foreign matter on the glass surface after the test, observation was performed using a digital microscope manufactured by Keyence Corporation. As a result, no foreign matter was found to have been generated on the glass surface according to any of Samples Nos. 1 to 19 and 41.

Meanwhile, the glass of each of Samples Nos. 49 to 52 underwent phase separation at the time of melting or at the time of forming, and hence the glass became opaque. As a result, the generation of foreign matter having a longest side of more than 100 pm was found on the glass surface according to each of Samples Nos. 49 to 52.

In Examples described above, the molten glass was poured out and formed into a flat sheet shape. However, when produced on an industrial scale, the glass is preferably formed into a flat sheet shape by an overflow down-draw method or the like, and used under a state in which both surfaces thereof are unpolished. In addition, when formed into a tube shape, the glass is preferably formed into a tube shape by a down-draw method, a Danner method, or the like.

### INDUSTRIAL APPLICABILITY

The UV transmitting glass of the present invention is suitable as, for example, glass to be used for a UV light-emitting diode (LED), a semiconductor package, a light-receiving element-encapsulating package, a UV light-emitting lamp, a photomultiplier tube, a reading and writing device for a magnetic recording medium, and other electronic devices each using a UV ray. In addition, the UV transmitting glass of the present invention is also applicable to an electronic device using visible light or infrared light.

1. A UV transmitting glass, comprising as a glass composition, in terms of mass %, 55% to 80% of SiO₂, 1% to 25% of Al₂O₃, 10.8% to 30% of B₂O₃, 0% to 10% of Na₂O, 0% to less than 1.6% of K₂O, 0.1% to 10% of Li₂O+Na₂O+K₂O, 0% to 5% of BaO, and 0% to 1% of Cl, and having an external transmittance at a thickness of 0.5 mm and a wavelength of 200 nm of 38% or more.

2. The UV transmitting glass according to claim 1, wherein the UV transmitting glass comprises as the glass composition, in terms of mass %, 65% to 74% of SiO₂, 3.5% to 20% of Al₂O₃, 11.5% to 25% of B203, 0.1% to 8% of Na₂O, 0% to 1% of K₂O, 1% to 10% of Li₂O+Na₂O+K₂O, 0% to 1.9% of BaO, 0.01% to 0.5% of Cl, and 0.00001% to 0.00200% of Fe₂O₃+TiO₂.

3. The UV transmitting glass according to claim 1, wherein, when the UV transmitting glass is subjected to a highly accelerated stress test (HAST) at a temperature of 121° C. and a relative humidity of 85% for a test time of 24 hours, a longest side of foreign matter generated on a surface of the glass is 100 μm or less.

4. The UV transmitting glass according to claim 1, wherein the UV transmitting glass has a temperature corresponding to glass viscosity Logp=6.0 dPa·s of 870° C. or less.

5. The UV transmitting glass according to claim 1, wherein the UV transmitting glass has a temperature corresponding to glass viscosity Logp=4.0 dPa·s of 1,200° C. or less.

6. The UV transmitting glass according to claim 1, wherein the UV transmitting glass has an average thermal expansion coefficient in a range of from 30° C. to 380° C. of from 40×10⁻⁷/° C. to 65×10⁻⁷/° C.

7. The UV transmitting glass according to claim 1, wherein the UV transmitting glass has an external transmittance at a thickness of 0.5 mm and a wavelength of 230 nm of 70% or more.

8. The UV transmitting glass according to claim 1, wherein the UV transmitting glass satisfies a relationship of T₂₀₀/T₂₆₀≥0.45, where T₂₀₀ represents the external transmittance (%) at a thickness of 0.5 mm and a wavelength of 200 nm, and T₂₆₀ represents an external transmittance (%) at a thickness of 0.5 mm and a wavelength of 260 nm.

9. The UV transmitting glass according to claim 1, wherein the UV transmitting glass has a functional film formed on a glass surface thereof.

10. The UV transmitting glass according to claim 1, wherein the UV transmitting glass has a lens structure formed on a glass surface thereof.

11. The UV transmitting glass according to claim 1, wherein the UV transmitting glass has a prism structure formed on a glass surface thereof.

12. The UV transmitting glass according to claim 1, wherein the UV transmitting glass has an adhesive layer formed on a glass surface thereof.

13. The UV transmitting glass according to claim 1, wherein the UV transmitting glass has a sheet shape or a tube shape, and has a thickness of from 0.1 mm to 3.0 mm.

14. The UV transmitting glass according to claim 1, wherein the UV transmitting glass has a tube shape, and has an inner diameter of 1 mm or more.

15. The UV transmitting glass according to claim 1, wherein the UV transmitting glass is used for any one of a UV light-emitting diode (LED), a semiconductor package, a light-receiving element-encapsulating package, a UV light-emitting lamp, and a photomultiplier tube.

16. The UV transmitting glass according to claim 2, wherein, when the UV transmitting glass is subjected to a highly accelerated stress test (HAST) at a temperature of 121° C. and a relative humidity of 85% for a test time of 24 hours, a longest side of foreign matter generated on a surface of the glass is 100 μm or less.

17. The UV transmitting glass according to claim 2, wherein the UV transmitting glass has a temperature corresponding to glass viscosity Logρ=6.0 dPa·s of 870° C. or less.

18. The UV transmitting glass according to claim 3, wherein the UV transmitting glass has a temperature corresponding to glass viscosity Logρ=6.0 dPa·s of 870° C. or less.

19. The UV transmitting glass according to claim 16, wherein the UV transmitting glass has a temperature corresponding to glass viscosity Logρ=6.0 dPa·s of 870° C. or less.

20. The UV transmitting glass according to claim 2, wherein the UV transmitting glass has a temperature corresponding to glass viscosity Logρ=4.0 dPa·s of 1,200° C. or less.
